(19) United States
(12) Patent Application Publication
(10) Pub. No.: US 2025/0237809 A1
(43) Pub. Date: Jul. 24, 2025

(54) PHOTONIC INTEGRATED CIRCUIT, METHOD OF MANUFACTURING THE SAME AND ELECTRONIC APPARATUS INCLUDING PHOTONIC INTEGRATED CIRCUIT

(71) Applicant: SAMSUNG ELECTRONICS CO., LTD., Suwon-si (KR)

(72) Inventors: Jungho Cha, Suwon-si (KR); Woosung Kim, Suwon-si (KR); Hyunil Byun, Suwon-si (KR); Changgyun Shin, Suwon-si (KR); Dongsik Shim, Suwon-si (KR); Bongyong Jang, Suwon-si (KR)

(73) Assignee: SAMSUNG ELECTRONICS CO., LTD., Suwon-si (KR)

(21) Appl. No.: 18/780,020

(22) Filed: Jul. 22, 2024

(30) Foreign Application Priority Data
Jan. 24, 2024 (KR) 10-2024-0010787

(51) Int. Cl. G02B 6/12; G02B 6/136

(52) U.S. Cl. CPC G02B 6/12004; G02B 6/136; G02B 2006/12061

(57) ABSTRACT

Provided are a photonic integrated circuit, a manufacturing method thereof, and an electronic apparatus including the photonic integrated circuit. The photonic integrated circuit includes a substrate, a light source, a light modulator optically connected to the light source, and a waveguide provided between the light source and the light modulator. The substrate includes a first groove and a second groove spaced apart from the first groove. The light source is provided in the first groove, the light modulator is provided in the second groove, the first and second active layers are in direct contact with the waveguide, and a height of the first and second active layers is between upper and lower surfaces of the waveguide.

### CROSS-REFERENCE TO RELATED APPLICATION

This application is based on and claims priority under 35 U.S.C. § 119 to Korean Patent Application No. 10-2024-0010787, filed on Jan. 24, 2024, in the Korean Intellectual Property Office, the disclosure of which is incorporated by reference herein in its entirety.

### BACKGROUND

### 1. Field

The disclosure relates to an optical interconnection, and more particularly, to a photonic integrated circuit and a manufacturing method thereof, and an electronic apparatus including the photonic integrated circuit.

### 2. Description of Related Art

In high-speed and large-capacity data communication between racks within a data center, the demand for technology to transmit data using photons is increasing as a way to solve limitations that arise when using copper conductors.

In order to use photons for data transmission between a central processing unit (CPU) and a memory, miniaturization of components used for long-distance optical communication is required.

To this end, there has recently been a growing interest in technology that integrates simultaneously a light source, a photonic integrated circuit, and a complementary metal oxide semiconductor integrated circuit (CMOS IC) by hybridizing a III/V light source on a silicon-on-insulator (SOI) substrate.

### SUMMARY

Provided is a photonic integrated circuit which may prevent or minimize the occurrence of a step.

Further, provided is a photonic integrated circuit which may minimize process constraints in a fabrication of CMOS logic.

Further, provided is a photonic integrated circuit capable of blocking the generation of gas by-products during a process of preparing a light source.

Further, provided is a photonic integrated circuit which may increase the efficiency of dissipating heat generated during an operation process.

Further, provided is a method of manufacturing the photonic integrated circuit.

Further, provided is an electronic apparatus including the photonic integrated circuit.

Additional aspects will be set forth in part in the description which follows and, in part, will be apparent from the description, or may be learned by practice of the presented embodiments of the disclosure.

According to an aspect of the disclosure, there is provided a photonic integrated circuit including: a substrate; a light source on the substrate, the light source including a first active layer configured to emit light; a light modulator on the substrate and optically connected to the light source, the light modulator including a second active layer configured to emit light; and a waveguide on the substrate between the light source and the light modulator, wherein the substrate includes: a first groove; and a second groove spaced apart from the first groove, wherein the light source is provided in the first groove, wherein the light modulator is provided in the second groove, wherein the first active layer and second active layer directly contact the waveguide, and wherein each of a first height of the first active layer and a second height of the second active layer is between an upper surface of the waveguide and a lower surface of the waveguide.

The light source may include a GaN-based material and the light modulator includes a GaN-based material.

A first planar size of the first groove may be same as a second planar size of the second groove, or a first depth of the first groove may be the same as a second depth of the second groove.

A first thickness of the first active layer may be different from a second thickness of the second active layer.

The substrate may include: a first semiconductor layer; a first insulating layer on the first semiconductor layer; and a second semiconductor layer on the first insulating layer, wherein the first semiconductor layer forms a bottom portion of the first groove and a bottom portion of the second groove.

The first semiconductor layer may be a silicon layer, and the bottom portion of the first groove and the bottom portion of the second groove are (111) planes.

A first width of the first active layer in a direction perpendicular to a length of the waveguide may be greater than a second width of the second active layer.

The substrate may include a trench corresponding to a length of the waveguide, wherein the trench penetrates the second semiconductor layer and has the first insulating layer as a bottom, and wherein a third thickness of the waveguide is the same as a fourth thickness of the second semiconductor layer.

The substrate may include: a first via hole including the first groove; a second via hole including the second groove; a third via hole including the waveguide; and a fourth via hole including a first pattern, which is a part of the substrate.

A first step may be provided between the first via hole and the first groove, and a second step may be provided between the second via hole and the second groove.

The first pattern may include: a first doped layer doped with a first dopant; and a second doped layer spaced apart from the first doped layer and doped with a second dopant that is different from the first dopant.

The first pattern may be adjacent to the waveguide and configured to receive light leaking from the waveguide.

The second semiconductor layer may include: a first via hole including the first groove; a second via hole including the second groove; a third via hole including the waveguide; and a fourth via hole including a first pattern, which is a part of the substrate, wherein the light source may include: a buffer layer and a first compound semiconductor layer provided in the first groove, the first compound semiconductor layer doped with an n-type dopant; a second compound semiconductor layer provided on a first region of the first compound semiconductor layer; the first active layer provided on the second compound semiconductor layer; and a third compound semiconductor layer provided on the first active layer and doped with a p-type dopant, wherein a first stack including the second compound semiconductor layer, the first active layer, and the third compound semiconductor layer is spaced apart from the second semiconductor layer, and wherein a thickness of the first stack is equal to a thickness of the second semiconductor layer.

The light modulator may include: the buffer layer and the first compound semiconductor layer in the second groove; a fourth compound semiconductor layer on a second region of the first compound semiconductor layer in the second groove; the second active layer on the fourth compound semiconductor layer; and a fifth compound semiconductor layer on the second active layer and doped with a p-type dopant, wherein a second stack including the fourth compound semiconductor layer, the second active layer, and the fifth compound semiconductor layer is spaced apart from the second semiconductor layer, and a thickness of the second stack is equal to a thickness of the second semiconductor layer, and wherein a second area of the second region is less than a first area of the first region.

According to another aspect of the disclosure, there is provided a method of manufacturing a photonic integrated circuit, the method including: forming, on a substrate, a first groove, a second groove, a third groove and a fourth groove, the first groove defining a region for forming a light source, the second groove defining a region for forming a light modulator, the third groove defining a region for forming a waveguide, and the fourth groove defining a region for forming a light receiving element; forming the waveguide in the third groove; forming a first sub-groove with a first width less than a second width of the first groove, and forming a second sub-groove with a third width less than a fourth width in the second groove; sequentially forming a first buffer layer and a first compound semiconductor layer doped with an n-type dopant in the first sub-groove; sequentially forming a second buffer layer and the first compound semiconductor layer in the second sub-groove; and forming a first stack including a first active layer on a first region on an upper surface of the first compound semiconductor layer in the first sub-groove and forming a second stack including a second active layer on a second region on the upper surface of the first compound semiconductor layer in the second sub-groove, wherein the first stack and the second stack are formed simultaneously to have at a same height as the waveguide, wherein the first sub-groove and the second sub-groove are formed simultaneously, wherein the first buffer layer and the second buffer layer are formed simultaneously, and wherein the first compound semiconductor layer in the first and second sub-grooves are formed simultaneously.

A height of the upper surface of the first compound semiconductor layer in the first and second sub-grooves may be the same as a height of a lower surface of the waveguide.

A first area of the first region and a second area of the second region may be different from each other.

A first thickness of the first active layer may be different from a second thickness of the second active layer.

According to another aspect of the disclosure, there is provided an electronic apparatus including: a photonic integrated circuit; and a semiconductor device connected to the photonic integrated circuit, wherein the photonic integrated circuit includes: a substrate; a light source on the substrate, the light source including a first active layer configured to emit light; a light modulator on the substrate and optically connected to the light source, the light modulator including a second active layer configured to emit light; and a waveguide on the substrate between the light source and the light modulator, wherein the substrate includes: a first groove; and a second groove spaced apart from the first groove, wherein the light source is provided in the first groove, wherein the light modulator is provided in the second groove, wherein the first active layer and second active layer directly contact the waveguide, and wherein each of a first height of the first active layer and a second height of the second active layer is between an upper surface of the waveguide and a lower surface of the waveguide.

The semiconductor device may include at least one of a memory and a processor.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a schematic cross-sectional view showing a semiconductor apparatus including an optical interconnect including a photonic integrated circuit and a semiconductor device according to an example embodiment;

FIG. 2A is a plan view showing a photonic integrated circuit included in first and second optical interconnection layers of FIG. 1;

FIG. 2B is a cross-sectional view showing a photonic integrated circuit included in first and second optical interconnection layers of FIG. 1;

FIG. 3 is a cross-sectional view taken along line 3-3′ of FIG. 2A;

FIGS. 4A-4B, 5A-5B, 6A-6B, 7A-7B, 8A-8B, 9A-9B, 10A-10B, 11, 12A-12B, 13, 14A-14B, 15A-15B, 16, 17A-17B, 18A-18B, 19A-19B, 20A-20B, 21A-21B, 22A-22B, 23, and 24 are views showing a method of manufacturing a photonic integrated circuit according to an example embodiment; and

FIG. 25 is a plan view showing a case in which a light receiving element is provided in a lateral direction of a waveguide in the manufacturing method of FIGS. 4A to 24.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a photonic integrated circuit, a manufacturing method thereof, and an electronic apparatus including the photonic integrated circuit according to an example embodiment will be described in detail with reference to the accompanying drawings. In the drawings, thicknesses of layers and regions may be exaggerated for clarification of the specification

The embodiments of the disclosure are capable of various modifications and may be embodied in many different forms. Hereinafter, when a position of an element is described using an expression “above” or “on”, the position of the element may include not only the element being “immediately on a contact manner” but also being “in a non-contact manner”. In the drawings, like reference numerals refer to the like elements.

The singular forms are intended to include the plural forms as well, unless the context clearly indicates otherwise. When a part “comprises” or “includes” an element in the specification, unless otherwise defined, it is not excluding other elements but may further include other elements.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the term “units” or “ . . . modules” denote units or modules that process at least one function or operation, and may be realized by hardware, software, or a combination of hardware and software.

Also, the connections of lines and connection members between constituent elements depicted in the drawings are examples of functional connection and/or physical or circuitry connections, and thus, in practical devices, may be expressed as replaceable or additional functional connections, physical connections, or circuitry connections.

All examples or example terms (for example, etc.) are simply used to explain in detail the technical scope of the inventive concept, and thus, the scope of the inventive concept is not limited by the examples or the example terms as long as it is not defined by the claims.

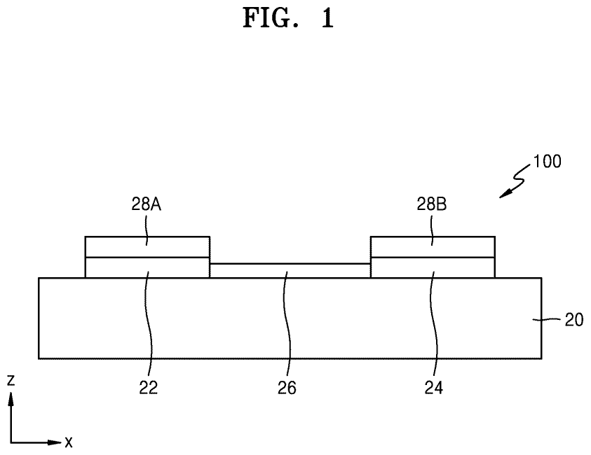

FIG. 1 is a schematic cross-sectional view showing a semiconductor apparatus 100 including an optical interconnect and a semiconductor device according to an example embodiment. The semiconductor apparatus 100 may also be expressed as an electronic apparatus.

Referring to FIG. 1, the semiconductor apparatus 100 may include a substrate 20, a first optical interconnection layer 22 and a second optical interconnection layer 24. The first and second optical interconnection layers 22 and 24 may be provided to be spaced apart from each other on the substrate 20. The first optical interconnection layer 22 and the second optical interconnection layer 24 may be optically connected to a light transmission medium 26 but are not limited thereto. Accordingly, light or optical signals generated by the first optical interconnection layer 22 and the second optical interconnection layer 24 may be transmitted from the first optical interconnection layer 22 to the second optical interconnection layer 22 through the light transmission medium 26, or vice versa. According to one or more example embodiments, the light transmission medium 26 and the first and second optical interconnection layers 22 and 24 may be directly connected. However, the disclosure is not limited thereto, and as such, according to another embodiment, the light transmission medium 26 may be spaced apart from the first and second optical interconnection layers 22 and 24. For example, the light transmission medium 26 may be spaced apart from the first and second optical interconnection layers 22 and 24 within a range that does not interfere with optical signal transmission. According to one or more example embodiments, the light transmission medium 26 may include, but the disclosure is not limited to, an optical waveguide or an optical fiber.

The first and second optical interconnection layers 22 and 24 may be expressed as first and second optical interconnections, first and second optical interconnectors, or first and second optical interconnection members (elements), etc.

A first semiconductor device 28A may be provided on the first optical interconnection layer 22, and a second semiconductor device 28B may be provided on the second optical interconnection layer 24. According to one or more example embodiments, one of the first and second semiconductor devices 28A and 28B may include a memory device, and the other may include an arithmetic processing unit. According to one or more example embodiments, the memory device may include volatile or non-volatile memory. For example, the memory device may include a dynamic random access memory (DRAM) or a static random access memory (SRAM), but the disclosure is not limited thereto. According to one or more example embodiments, the arithmetic processing unit may include, but is not limited to, a central processing unit (CPU) or a processor. According to one or more example embodiments, the first optical interconnection layer 22 and the first semiconductor device 28A may be coupled to each other by a pin method to exchange electrical signals (data) with each other and may be coupled by methods other than the pin method. According to one or more example embodiments, the second optical interconnection layer 24 and the second semiconductor device 28B may be coupled to each other using a pin method to exchange electrical signals with each other and may be coupled by methods other than the pin method. However, the disclosure is not limited thereto, and as such, according to another embodiment, an optical interconnection layer and a semiconductor device may be connected to each coupled to each other in another manner.

According to one or more example embodiments, the first optical interconnection layer 22 may include a first element for converting an electrical signal received from the first semiconductor device 28A into an optical signal, a second element for transmitting the optical signal to the optical transmission medium 26 by processing the optical signal, a third element for receiving the optical signal from the optical transmission medium 26, a fourth element for processing the received optical signal, and a fifth element for converting the processed optical signal into an electrical signal and transmitting the processed optical signal to the first semiconductor device 28A. According to one or more example embodiments, the first optical interconnection layer 22 may include a first photonic integrated circuit (PIC) including the first to fifth elements, but the disclosure is not limited thereto. According to one or more example embodiments, at least some of the first to fifth elements may be optical devices or may include optical elements or optical members.

According to one or more example embodiments, the second optical interconnection layer 24 may include a sixth element for converting the electrical signal received from the second semiconductor device 28B into an optical signal, a seventh element for transmitting the optical signal to the optical transmission medium 26 by processing the optical signal, an eighth element for receiving the optical signal from the optical transmission medium 26, a ninth element for processing the received optical signal, and a tenth element for converting the processed optical signal into an electrical signal and transmitting the processed optical signal to the second semiconductor device 28B. According to one or more example embodiments, the second optical interconnection layer 24 may include a second photonic integrated circuit including the sixth to tenth elements, but the disclosure is not limited thereto. According to one or more example embodiments, at least some of the sixth to tenth elements may be optical elements or may include optical elements.

According to one or more example embodiments, the first photonic integrated circuit may include a light source that is a light emission source, a light modulator configured to modulate a phase or amplitude of light emitted from the light source according to a given control signal (or data signal), a light receiving element (e.g., photodiode) for receiving light, a waveguide, a logic circuit, etc. The second photonic integrated circuit may also include elements included in the first photonic integrated circuit, but the disclosure is not limited thereto. Elements (optical elements or non-optical elements) included in the first photonic integrated circuit may be the same as or different from elements included in the second photonic integrated circuit.

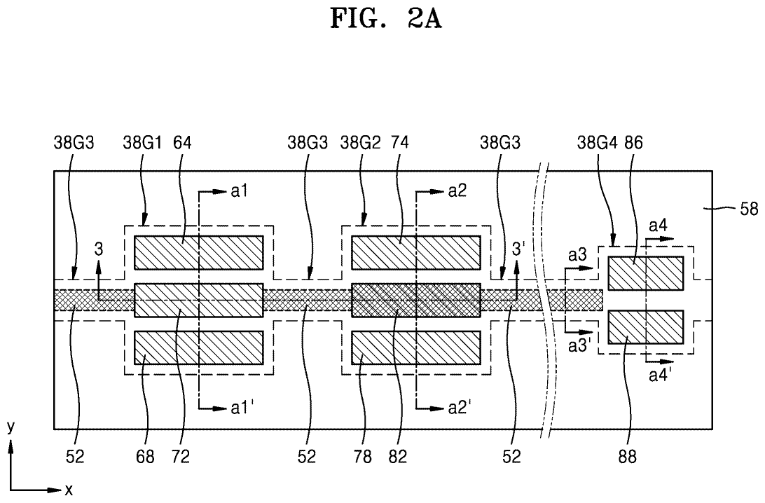

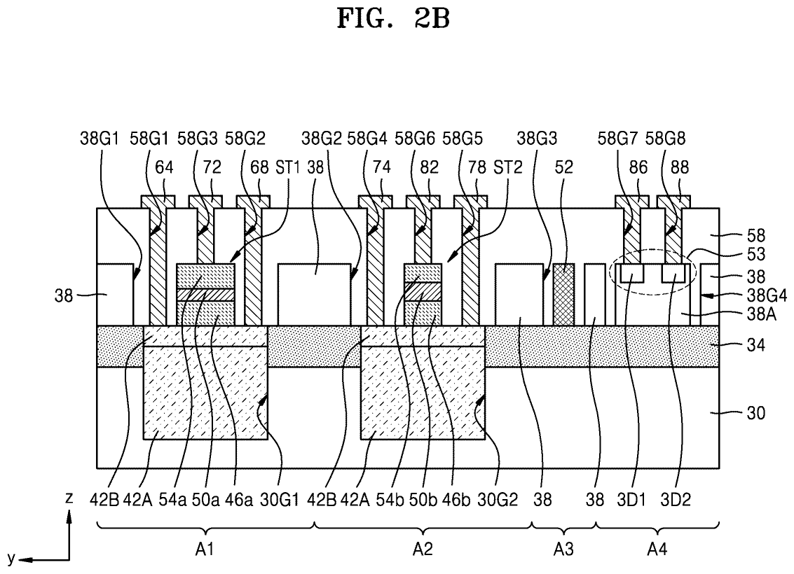

FIGS. 2A and 2B show a photonic integrated circuit included in the first and second optical interconnection layers 22 and 24.

For convenience of illustration and explanation, FIGS. 2A and 2B show only a light source, a light modulator, a light receiving element, and a waveguide among the elements included in the photonic integrated circuit. However, the substrate 20 may be further equipped with other devices or elements included in the photonic integrated circuit, such as an optical splitter or logic transistor.

FIG. 2A shows a plan view of a photonic integrated circuit, and FIG. 2B shows a cross-section of various parts of the photonic integrated circuit illustrated in FIG. 2A. In FIG. 2B, A1 represents a cross-sectional view taken along line a1-a1′ of FIG. 2A, A2 represents a cross-sectional view taken along line a2-a2′ of FIG. 2A, A3 represents a cross-sectional view taken along line a3-a3′ of FIG. 2A, and A4 represents cross-sectional view taken along line a4-a4′ of FIG. 2A.

Referring to FIGS. 2A and 2B, the photonic integrated circuit may include a first semiconductor layer 30, a first insulating layer 34, and a second semiconductor layer 38. For example, the first semiconductor layer 30, the first insulating layer 34, and the second semiconductor layer 38 may be sequentially stacked. The first and second semiconductor layers 30 and 38 may include a same semiconductor material or different semiconductor materials. According to one or more example embodiments, the first semiconductor layer 30, the first insulating layer 34, and the second semiconductor layer 38 may be collectively represented as one substrate layer. According to one or more example embodiments, the first semiconductor layer 30, the first insulating layer 34, and the second semiconductor layer 38 may form one SOI substrate. According to one or more example embodiments, the first semiconductor layer 30 may be or may include a silicon layer, but the disclosure is not limited thereto. In an example case in which the first semiconductor layer 30 is a silicon layer, an upper surface thereof may be a (111) crystal plane, but the disclosure is not limited thereto. According to one or more example embodiments, a thickness of the first semiconductor layer 30 may be in a range from about 3 μm to about 10 μm, but the disclosure is not limited thereto. For example, the thickness of the first semiconductor layer 30 may be greater than a depth of a portion of a first groove 30G1 extending into the first semiconductor layer 30. According to one or more example embodiments, the first insulating layer 34 may include oxide or nitride, but the disclosure is not limited thereto. As an example, the first insulating layer 34 may include silicon oxide (SiO₂), but the disclosure is not limited thereto. The first insulating layer 34 may have a thickness that may minimize or prevent leakage of light transmitted through a waveguide 52 provided on the first insulating layer 34. The waveguide 52 may also be expressed as a wave path 52 or a wave guiding path 52. As an example, the first insulating layer 34 may have a thickness that may minimize or prevent light leakage from the waveguide 52 to the first semiconductor layer 30, and the thickness may be 500 nm or more, but the disclosure is not limited thereto. For example, the thickness of the first insulating layer 34 may be less than 500 nm depending on a material used as the first insulating layer 34. An upper limit of the thickness of the first insulating layer 34 may be determined by considering an overall thickness of the photonic integrated circuit or a thickness of the substrate layer. The second semiconductor layer 38 may be a silicon layer or may include the silicon layer, but the disclosure is not limited thereto. In an example case in which the second semiconductor layer 38 includes a silicon layer, a crystal plane of an upper surface of the second semiconductor layer 38 may be (100), but the disclosure is not limited thereto. According to one or more example embodiments, the thickness of the second semiconductor layer 38 may be in a range from about 200 nm to about 400 nm, but the disclosure is not limited thereto.

The second semiconductor layer 38 may include a first via holes 38G1, a second via hole 38G2, and a third via hole 38G3. The first insulating layer 34 may be exposed through the first to third via holes 38G1, 38G2, and 38G3. The second semiconductor layer 38 may further include at least one via hole in addition to the first to third via holes 38G1, 38G2, and 38G3. The via holes 38G1, 38G2, and 38G3 may also be expressed as ‘vias’ or ‘through holes’. In addition, in an example case in which a layer structure including the first semiconductor layer 30, the first insulating layer 34, and the second semiconductor layer 38 is viewed as one substrate layer, the first to third via holes 38G1, 38G2, and 38G3 may also be regarded as a plurality of grooves formed in one substrate layer.

The first to third via holes 38G1, 38G2, and 38G3 are spaced apart from each other. A first groove 30G1 having a width less than the first via hole 38G1 is formed inside the first via hole 38G1. In an example case in which the first via hole 38G1 is expressed as a groove, the first groove 30G1 may be expressed as a sub-groove or a first sub-groove. The first groove 30G1 is spaced apart from a side of the first via hole 38G1. That is, a step exists between the first groove 30G1 and the first via hole 38G1. The first groove 30G1 penetrates the first insulating layer 34 and extends into the first semiconductor layer 30 to a given depth. A bottom of the first groove 30G1 is spaced apart from a bottom of the first semiconductor layer 30. A depth of the first groove 30G1 may be in a range from about 3 μm to about 8 μm, but the disclosure is not limited thereto.

The first groove 30G1 include a first buffer layer 42A and a first compound semiconductor layer 42B. For example, the first groove 30G1 may be filled with the first buffer layer 42A and the first compound semiconductor layer 42B sequentially stacked. The first buffer layer 42A and the first compound semiconductor layer 42B may be sequentially grown by using an epitaxial growth method. For example, the growth method may include, but the disclosure is not limited to, a selective hetero-epitaxy method. According to another embodiment, one or more other layers may be provided in the first groove 30G1.

According to one or more example embodiments, the first buffer layer 42A may be a single buffer layer but may include multiple layers. According to one or more example embodiments, the first buffer layer 42A may include a Group III-V compound semiconductor, but the disclosure is not limited thereto. According to one or more example embodiments, the first buffer layer 42A may include a lower buffer layer, an intermediate buffer layer, and an upper buffer layer that are vertically stacked sequentially on the bottom of the first groove 30G1. According to one or more example embodiments, the lower buffer layer may include, but the disclosure is not limited to, an aluminum nitride (e.g., AlN) buffer layer. According to one or more example embodiments, the intermediate buffer layer may include an AlGaN buffer layer, but the disclosure is not limited thereto. According to one or more example embodiments, the upper buffer layer may include, but the disclosure is not limited to, a GaN buffer layer. The GaN buffer layer may include an undoped GaN layer.

According to one or more example embodiments, the first compound semiconductor layer 42B may be an n-type compound semiconductor layer doped with an n-type conductive dopant. For example, the first compound semiconductor layer 42B may include a Group III-V compound semiconductor layer doped with an n-type conductive dopant. According to one or more example embodiments, the Group III-V compound semiconductor layer may include GaN, but the disclosure is not limited thereto.

An upper surface of the first compound semiconductor layer 42B may be flat and may form the same plane as an upper surface of the first insulating layer 34. For example, a height of the upper surface of the first compound semiconductor layer 42B may be the same or substantially the same as a height of the upper surface of the first insulating layer 34. According to an embodiment, a second compound semiconductor layer 46a, a first active layer 50a, and a third compound semiconductor layer 54a may be provided on the first compound semiconductor layer 42B. The second compound semiconductor layer 46a, the first active layer 50a, and the third compound semiconductor layer 54a may be sequentially stacked on the first compound semiconductor layer 42B. The second compound semiconductor layer 46a, the first active layer 50a, and the third compound semiconductor layer 54a may be sequentially grown using the growth method mentioned above. According to one or more example embodiments, a thickness of the first layer structure (first stack) ST1 including the second compound semiconductor layer 46a, the first active layer 50a, and the third compound semiconductor layer 54a may be in a range from about 200 nm to about 400 nm. The thickness of the first layer structure (first stack) ST1 may be determined considering a thickness of the waveguide 52, and may vary depending on the thickness of the waveguide 52, but may be substantially the same as the thickness of the waveguide 52 or may be less than the thickness of the waveguide 52.

According to one or more example embodiments, the second compound semiconductor layer 46a may be a superlattice layer, but the disclosure is not limited to this. According to one or more example embodiments, the second compound semiconductor layer 46a may include a layer structure in which an InGaN layer and a GaN layer are sequentially stacked or grown. According to one or more example embodiments, the second compound semiconductor layer 46a may include a layer structure in which InGaN layers and GaN layers are repeatedly and alternately stacked (grown). The first active layer 50a may include, but the disclosure is not limited to, a multiple quantum well (MQW) structure. According to one or more example embodiments, the third compound semiconductor layer 54a may include a p-type compound semiconductor layer doped with a p-type conductive impurity or a p-type dopant. According to one or more example embodiments, the p-type compound semiconductor layer may include a Group III-V compound semiconductor material (e.g., GaN) as a compound semiconductor material, but the disclosure is not limited thereto.

Widths of the second compound semiconductor layer 46a, the first active layer 50a, and the third compound semiconductor layer 54a may be substantially the same. The first layer structure ST1 including the second compound semiconductor layer 46a, the first active layer 50a, and the third compound semiconductor layer 54a may be provided on the first compound semiconductor layer 42B and may be spaced apart from the second semiconductor layer 38. For example, the first layer structure ST1 may be spaced apart or away from an inner surface of the first via hole 38G1. Also, the first layer structure ST1 may be spaced apart or away from an edge of the first groove 30G1.

A height or a height of an upper surface of the third compound semiconductor layer 54a of the first layer structure ST1 may be the same or substantially the same as a height of the upper surface of the second semiconductor layer 38.

The first buffer layer 42A and the first compound semiconductor layer 42B filling the first groove 30G1, and the second compound semiconductor layer 46a, the first active layer 50a, and the third compound semiconductor layer 54a provided on the first compound semiconductor layer 42B may form a first light-emitting device. This first light-emitting device may act as a light source of a transmitting unit. According to one or more example embodiments, the first light-emitting device may emit light with a wavelength in a range from about 400 nm to about 500 nm, but the disclosure is not limited thereto. According to one or more example embodiments, the first light-emitting device may include a device (e.g., a laser diode) that emits a laser of the wavelength or may include a light-emitting diode (LED).

The first light-emitting device is formed in the first groove 30G1. Therefore, heat generated during an operation of the first light-emitting device, for example, heat generated in the first active layer 50a may be transferred directly to the first semiconductor layer 30 connected to a heat sink without passing through the first insulating layer 34, which has low thermal conductivity. Accordingly, the heat emission efficiency of the first light-emitting device may be increased. For the same reason, the heat emission efficiency of the second light-emitting device (light modulator), which will be described below, may also be increased.

In addition, because the first light-emitting device is provided in the first groove 30G1 and in a manufacturing process, a planarization process is performed after the first light-emitting device is formed, the first light-emitting device may not have a portion protruding above the second semiconductor layer 38. As a result, the first light-emitting device may not generate a step difference. Accordingly, after the photonic integrated circuit is formed, a subsequent manufacturing process of other semiconductor devices, such as a CMOS logic process, may proceed smoothly without being affected by the step difference. In addition, the first light-emitting device, which is formed in a relatively high-temperature process, is formed first and the CMOS logic process is performed at a relatively lower temperature than the process of forming the first light-emitting device, and thus, during the CMOS logic process is performed, there is no need to worry about deterioration or degradation of the characteristics of the first light-emitting device. That is, at least in terms of process temperature, limitations on CMOS logic process may disappear or be minimized.

Inside the second via hole 38G2, a second groove 30G2 having a width (diameter) less than a width of the second via hole 38G2 may be formed. In an example case in which the second via hole 38G2 is expressed as a groove, the second groove 30G2 may be expressed as a sub-groove or a second sub-groove.

As shown in FIG. 2A, in a plan view, an area of the second via hole 38G2 and an area of the first via hole 38G1 may be the same or substantially the same but are not limited thereto. An area of the first groove 30G1 and an area of the second groove 30G2 may also be the same or substantially the same but are not limited thereto.

A width and depth of the second groove 30G2 may be the same or substantially the same as the first groove 30G1 but are not limited thereto. The second groove 30G2 is spaced apart from the adjacent second semiconductor layer 38 on a circumference. That is, the second groove 30G2 is spaced apart from an inner surface of the second via hole 38G2. Accordingly, a step difference may exist between the second via hole 38G2 and the second groove 30G2.

Like the first groove 30G1, the second groove 30G2 may be filled with the first buffer layer 42A and the first compound semiconductor layer 42B, which are sequentially formed.

A fourth compound semiconductor layer 46b, a second active layer 50b, and a fifth compound semiconductor layer 54b are sequentially formed on the first compound semiconductor layer 42B in the second groove 30G2. The fourth compound semiconductor layer 46b, the second active layer 50b, and the fifth compound semiconductor layer 54b may be formed sequentially using the growth method described above. According to one or more example embodiments, a material of the fourth compound semiconductor layer 46b may be the same as the material of the second compound semiconductor layer 46a, but the disclosure is not limited thereto. According to one or more example embodiments, a thickness of the fourth compound semiconductor layer 46b may be different from the thickness of the second compound semiconductor layer 46a but may be the same. According to one or more example embodiments, a material of the second active layer 50b may be the same as the material of the first active layer 50a, but the disclosure is not limited thereto. According to one or more example embodiments, a thickness of the second active layer 50b may be different from the thickness of the first active layer 50a, but may be the same or substantially the same. For example, the thickness of the second active layer 50b may be greater than the first active layer 50a. A thickness difference may increase a bandgap difference, thereby reducing a light absorption rate in the light modulator, and as a result, the modulation characteristics of the light modulator may be improved.

According to one or more example embodiments, a material of the fifth compound semiconductor layer 54b may be the same as the material of the third compound semiconductor layer 54a, but the disclosure is not limited thereto. According to one or more example embodiments, the thickness of the fifth compound semiconductor layer 54b may be different from the thickness of the third compound semiconductor layer 54a but may be the same. A height of the fifth compound semiconductor layer 54b or a height of an upper surface of the fifth compound semiconductor layer 54b may be equal to or substantially the same as the height of the second semiconductor layer 38 or the height of the upper surface of the second semiconductor layer 38.

A second layer structure (second stack) ST2 including the fourth compound semiconductor layer 46b, the second active layer 50b, and the fifth compound semiconductor layer 54b is spaced apart from the second semiconductor layer 38. In other words, the second layer structure ST2 is away from an inner side of the second via hole 38G2. The second layer structure ST2 is spaced apart from an edge of the second groove 30G2.

A gap (or distance) between the second layer structure ST2 and the second semiconductor layer 38 may be greater than a gap between the first layer structure ST1 and the second semiconductor layer 38, but the disclosure is not limited to this. A width of the second layer structure ST2 in a y-axis direction or in a direction perpendicular to a length of the waveguide 52 may be less than a width of the first layer structure ST1 in the same direction, but the disclosure is not limited thereto.

The first buffer layer 42A and the first compound semiconductor layer 42B filling the second groove 30G2 and the fourth compound semiconductor layer 46b, the second active layer 50b, the fifth compound semiconductor layer 54b provided on the first compound semiconductor layer 42B may form a second light-emitting device. The second light-emitting device may be included in the transmitting unit equipped with the first light-emitting device (light source) and may function as a light modulator. According to one or more example embodiments, the second light-emitting device may emit modulated or unmodulated light with a wavelength in a range from about 400 nm to about 500 nm, but the disclosure is not limited thereto. According to one or more example embodiments, the second light-emitting device used as a light modulator may use an electro-absorption method. Therefore, the second light-emitting device may function as a light modulator not only in a case in which the first light-emitting device used as a light source is a device (e.g., a laser diode) that emits a laser of the wavelength, but also in a case in which the first light-emitting device is an LED.

In an example case in which the first light-emitting device used as a light source includes a laser diode and directly modulates or is provided to directly modulate the laser diode, the second light-emitting device may not be used.

The optical waveguide 52 is provided on the first insulating layer 34 exposed through the third via hole 38G3. The optical waveguide 52 may be provided between the first active layer 50a of the first light-emitting device and the second active layer 50b of the second light-emitting device, and between the second active layer 50b of the second light-emitting device and a light receiving element 53 formed on the first pattern 38A of the second semiconductor layer 38.

The waveguide 52 is provided directly on the first insulating layer 34 and may be in direct contact with the first insulating layer 34. However, the disclosure is not limited thereto, and as such, according to another embodiment, another layer may be provided between the waveguide 52 and the first insulating layer 34. The waveguide 52 is spaced apart from the second semiconductor layer 38. In other words, the waveguide 52 is spaced apart from an inner side of the third via hole 38G3. A height of the waveguide 52 or a height of an upper surface of the waveguide 52 may be the same or substantially the same as the height of the second semiconductor layer 38 or the height of the upper surface of the second semiconductor layer 38. According to an embodiment, because the waveguide 52 is formed at the same height as the light receiving element 53, light transmitted through the waveguide 52 may be directly incident on the light receiving element 53.

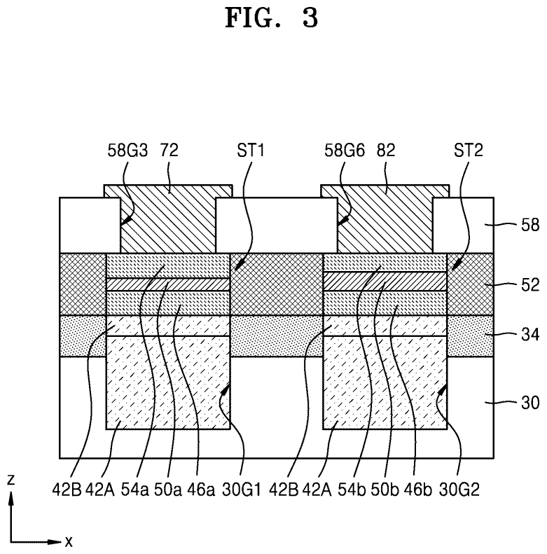

FIG. 3 shows a cross-sectional view taken along line 3-3′ of FIG. 2A.

Referring to FIG. 3, a height of the waveguide 52 may be the same or substantially the same as the height of the first layer structure ST1. In other words, the height of an upper surface of the waveguide 52 may be the same or substantially the same as a height of the upper surface of the third compound semiconductor layer 54a of the first layer structure ST1. The waveguide 52 may be in direct contact with the first active layer 50a of the first light-emitting device and the second active layer 50b of the second light-emitting device. Additionally, the first and second active layers 50a and 50b may be positioned between the lower and upper surfaces of the waveguide 52 in a vertical direction. In other words, a height of the lower surface of the first and second active layers 50a and 50b may be higher than a height of a lower surface of the waveguide 52, and a height of an upper surface of the first and second active layers 50a and 50b may be lower than the height of the upper surface of the waveguide 52. Accordingly, light emitted from the first active layer 50a may be focused into the waveguide 52, and modulated or unmodulated light emitted from the second active layer 50b may also be focused into the waveguide 52.

According to one or more example embodiments, the waveguide 52 may be a waveguide including silicon nitride or titanium oxide (TiO₂), but the disclosure is not limited thereto. In other words, the waveguide 52 may include, but the disclosure is not limited to, silicon nitride or titanium oxide.

Referring again to FIGS. 2A and 2B, the light receiving element 53 is provided in the second semiconductor layer 38. The light receiving element 53 may include a first doped layer 3D1 and a second doped layer 3D2 spaced apart from each other. In some examples, ‘doped layer’ may also be expressed as ‘doped region. One of the first and second doped layers 3D1 and 3D2 may be a p-type doped region, and the other may be an n-type doped region. The second semiconductor layer 38 between the first doped layer 3D1 and the second doped layer 3D2 may be a channel layer or a channel region. In an example case in which light is incident on the channel layer while a voltage is applied to the first and second doped layers 3D1 and 3D2, photoelectrons generated in the channel layer flow through the channel layer. That is, a current flows in the channel between the first and second doped layers 3D1 and 3D2, and by detecting the current, it may be recognized that light or an optical signal has been received by the light receiving element 53. The light receiving element 53 may include, but the disclosure is not limited to, a photo diode.

The channel layer of the light receiving element 53 may be provided close to the waveguide 52 while being spaced apart from the waveguide 52. Accordingly, light in the form of an evanescent wave generated in the waveguide 52 may be received by the light receiving element 53.

The light receiving element 53 may be included in a receiving unit of a photonic integrated circuit. The light receiving element 53 may be provided at a location spatially spaced apart from the first and second light-emitting elements included in the transmitting unit of the photonic integrated circuit.

An upper insulating layer 58 may be formed on the second semiconductor layer 38. The upper insulating layer 58 may be provided to cover an entire upper surface of the second semiconductor layer 38 around the first to third via holes 38G1, 38G2, and 38G3. The upper insulating layer 58 may be in direct contact with the entire upper surface of the second semiconductor layer 38, but the disclosure is not limited thereto. An upper surface of the upper insulating layer 58 may be flat. The upper insulating layer 58 may be provided to fill the first to third via holes 38G1, 38G2, and 38G3 and to cover the first layer structure ST1 in the first via hole 38G1, the second layer structure ST2 in the second via hole 38G2, the waveguide 52 in the third via hole 38G3, and the light receiving element 53.

According to one or more example embodiments, the upper insulating layer 58 may include, but the disclosure is not limited to, a silicon oxide (SiO₂) layer.

According to an embodiment, a first through hole 58G1, a second through hole 58G2, and a third through hole 58G3 penetrating the upper insulating layer 58 may be provided in a region corresponding to the first via hole 38G1 of the upper insulating layer 58. The third through hole 58G3 may be located between the first and second through holes 58G1 and 58G2. The first and second through holes 58G1 and 58G2 may be located on both sides of the first layer structure ST1. The first and second through holes 58G1 and 58G2 are spaced apart from the first layer structure ST1 and the second semiconductor layer 38. The first and second through holes 58G1 and 58G2 may be provided so that the first compound semiconductor layer 42B in the first groove 30G1 is exposed through the first and second through holes 58G1 and 58G2. The upper surface of the first compound semiconductor layer 42B in the first groove 30G1 may be exposed through the first and second through holes 58G1 and 58G2.

The third through hole 58G3 may be located on the first layer structure ST1. The third through hole 58G3 may be provided so that the third compound semiconductor layer 54a of the first layer structure ST1 is exposed through the third through hole 58G3. The upper surface of the third compound semiconductor layer 54a may be exposed through the third through hole 58G3.

The first through hole 58G1 is filled with a first electrode (layer) 64, the second through hole 58G2 is filled with a second electrode (layer) 68, and the third through hole 58G3 is filled with a third electrode (layer) 72. The first and second electrodes 64 and 68 may be in contact with the upper surface of the first compound semiconductor layer 42B in the first groove 30G1 but are not limited to this. For example, a metal thin film for ohmic contact may further be provided between the first and second electrodes 64 and 68 and the first compound semiconductor layer 42B.

The third electrode 72 may be in contact with the upper surface of the third compound semiconductor layer 54a, but the disclosure is not limited thereto. For example, a metal thin film for ohmic contact may further be provided between the third electrode 72 and the third compound semiconductor layer 54a.

On an upper surface of the upper insulating layer 58, the first to third electrodes 64, 68, and 72 are spaced apart from each other.

According to an embodiment, a fourth through hole 58G4, a fifth through hole 58G5, and a sixth through hole 58G6 may be provided in a region corresponding to the second via hole 38G2 of the upper insulating layer 58.

The sixth through hole 58G6 is located between the fourth and fifth through holes 58G4 and 58G5. The fourth and fifth through holes 58G4 and 58G5 may be located on both sides of the second layer structure ST2. The fourth and fifth through holes 58G4 and 58G5 are spaced apart from the second layer structure ST2 and the second semiconductor layer 38. The fourth and fifth through holes 58G4 and 58G5 may be provided so that the first compound semiconductor layer 42B in the second groove 30G2 is exposed through the fourth and fifth through holes 58G4 and 58G5. The upper surface of the first compound semiconductor layer 42B in the second groove 30G2 may be exposed through the fourth and fifth through holes 58G4 and 58G5.

The sixth through hole 58G6 may be located on the second layer structure ST2. The sixth through hole 58G6 may be provided so that the fifth compound semiconductor layer 54b of the second layer structure ST2 is exposed through the sixth through hole 58G6. The upper surface of the fifth compound semiconductor layer 54b may be exposed through the sixth through hole 58G6.

The fourth through hole 58G4 is filled with a fourth electrode (layer) 74, the fifth through hole 58G5 is filled with a fifth electrode (layer) 78, and the sixth through hole 58G6 is filled with a sixth electrode (layer) 82. The fourth and fifth electrodes 74 and 78 may be in contact with the upper surface of the first compound semiconductor layer 42B in the second groove 30G2 but are not limited to this. For example, a metal thin film for ohmic contact may further be provided between the fourth and fifth electrodes 74 and 78 and the first compound semiconductor layer 42B.

The sixth electrode 82 may be in contact with the upper surface of the fifth compound semiconductor layer 54b, but the disclosure is not limited to this. For example, a metal thin film for ohmic contact may further be provided between the sixth electrode 82 and the fifth compound semiconductor layer 54b.

On the upper surface of the upper insulating layer 58, the fourth to sixth electrodes 74, 78, and 82 are spaced apart from each other.

According to an embodiment, a seventh through hole 58G7 and an eighth through hole 58G8 may be provided in a region corresponding to the light receiving element 53 of the upper insulating layer 58. The seventh and eighth through holes 58G7 and 58G8 are spaced apart from each other. The seventh through hole 58G7 may be located on the first doped layer 3D1, and the eighth through hole 58G8 may be located on the second doped layer 3D2. The first doped layer 3D1 may be exposed through the seventh through hole 58G7, and the second doped layer 3D2 may be exposed through the eighth through hole 58G8. The seventh through hole 58G7 is filled with a seventh electrode (layer) 86, and the eighth through hole 58G8 is filled with an eighth electrode (layer) 88. The seventh electrode 86 may be in direct contact with the first doped layer 3D1, but the disclosure is not limited to this. The eighth electrode 88 may be in direct contact with the second doped layer 3D2, but the disclosure is not limited to this. On the upper insulating layer 58, the seventh electrode 86 and the eighth electrode 88 are spaced apart from each other.

Heights of the first to eighth electrodes 64, 68, 72, 74, 78, 82, 86, and 88 on the upper insulating layer 58 may be the same. Each of the first to eighth electrodes 64, 68, 72, 74, 78, 82, 86, and 88 may be expanded onto the upper insulating layer 58 around each of the corresponding through holes 58G1 to 58G8, and the degree of expansion may be limited because non-contact with other electrodes is needed to be maintained.

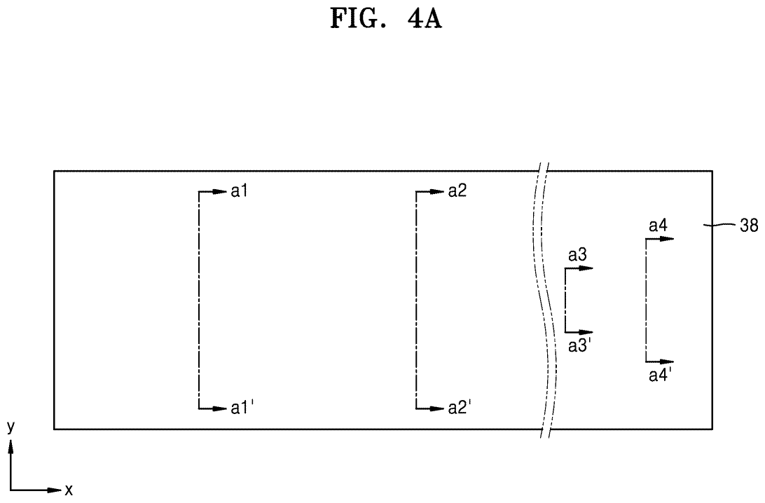

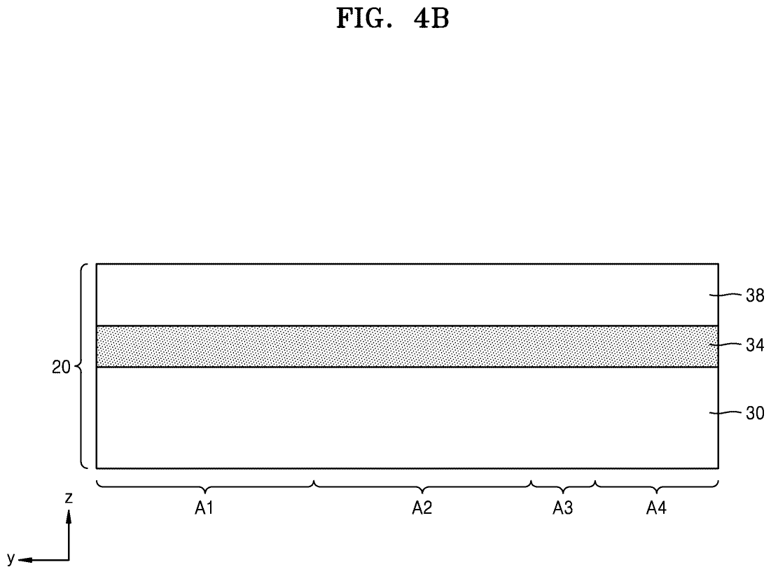

Next, a method of manufacturing a photonic integrated circuit according to an embodiment will be described with reference to FIGS. 4 to 25.

Reference numbers that are the same as those mentioned in the description of FIGS. 2A, 2B and 3 indicate the same members, and descriptions thereof are omitted.

As in the case of FIGS. 2A and 2B, FIGS. 4A to 10A, 12A, 14A, 15A, and 17A to 22A are plan views, and FIGS. 4B to 10B, 12B, 14B, 15B, and FIGS. 17B to 22B are cross-sectional views of various portions of FIGS. 4A to 10A, 12A, 14A, 15A, and 17A to 22A, respectively. In FIGS. 4B to 10B, 12B, 14B, 15B, and 17B to 22B, A1 represents a cross-sectional view taken along line a1-a1′ of each of FIGS. 4A to 10A, 12A, 14A, 15A, and 17A to 22A, A2 represents a cross-sectional view taken along line a2-a2′, A3 represents a cross-sectional view taken along line a3-a3′, and A4 represents a cross-sectional view taken along line a4-a4′, respectively.

As shown in FIGS. 4A and 4B, a substrate 20 having a first semiconductor layer 30, a first insulating layer 34, and a second semiconductor layer 38 is prepared. For example, the substrate 20 may include the first semiconductor layer 30, the first insulating layer 34, and the second semiconductor layer 38 sequentially stacked. According to one or more example embodiments, the first semiconductor layer 30 may include a silicon layer. Considering the selective hetero-growth of a subsequent compound semiconductor layer (e.g., GaN), the first semiconductor layer 30 may be formed so that an upper surface of the first semiconductor layer 30 is a (111) plane, but the disclosure is not limited thereto.

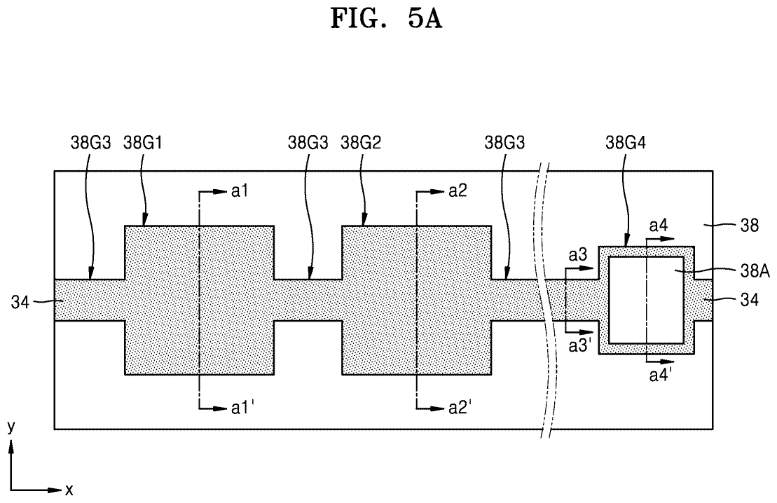

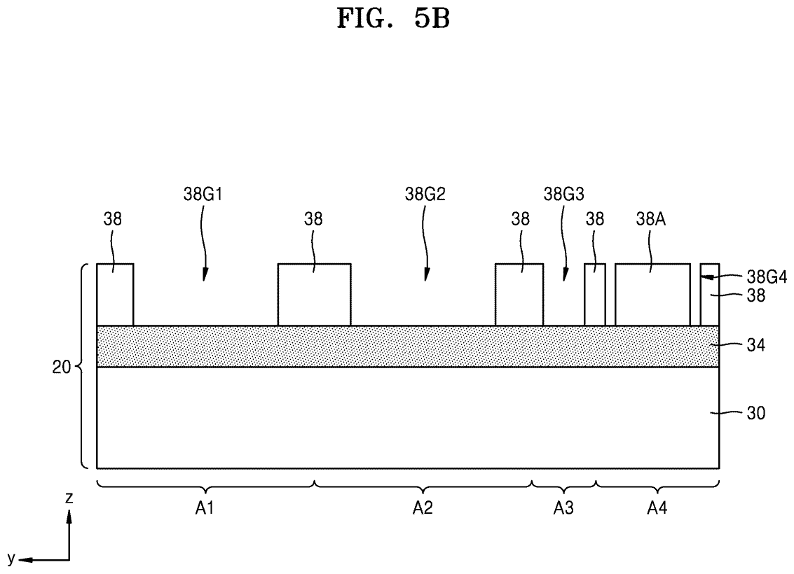

Next, as shown in FIGS. 5A and 5B, the second semiconductor layer 38 is patterned to form first to fourth via holes 38G1 to 38G4 through which the first insulating layer 34 is exposed. The patterning of the second semiconductor layer 38 may be performed using a dry etching method, but the disclosure is not limited thereto. The first via hole 38G1 may define a region where a light source will be formed, the second via hole 38G2 may define a region where a light modulator will be formed, and the third via hole 38G3 may define a region where a waveguide will be formed. The fourth via hole 38G4 may define a region where a light receiving element will be formed. The patterning of the second semiconductor layer 38 may be performed so that the first pattern 38A of the second semiconductor layer 38 remains in the fourth via hole 38G4. The first pattern 38A may be spaced apart from an inner surface of the fourth via hole 38G4. That is, the first pattern 38A is spaced apart from the surrounding second semiconductor layer 38. Accordingly, a gap may exist between the first pattern 38A and the inner side of the fourth via hole 38G4. The first to fourth via holes 38G1 to 38G4 may be one via hole connected to each other, but may not be one via hole.

As shown in FIG. 5A, a planar shape of the first and second via holes 38G1 and 38G2 may be square, but the disclosure is not limited thereto. Planar sizes of the first and second via holes 38G1 and 38G2 may be the same but may also be different. The first and second via holes 38G1 and 38G2 are spaced apart from each other but may be connected to each other through the third via hole 38G3. The second via hole 38G2 and the fourth via hole 38G4 may also be connected to each other by the third via hole 38G3. Widths of the first and second via holes 38G1 and 38G2 in a first direction, that is, widths in a direction perpendicular to a longitudinal direction of the third via hole 38G3 (e.g., y-axis direction), may be the same or substantially the same and may be greater than a width of the third via hole 38G3. A width of the fourth via hole 38G4 in the first direction may be greater than the width of the third via hole 38G3 and less than the widths of the first and second via holes 38G1 and 38G2. A planar shape of the fourth via hole 38G4 may be square, but the disclosure is not limited thereto. The planar size of the fourth via hole 38G4 may be less than the planar size of the first and second via holes 38G1 and 38G2, but the disclosure is not limited thereto.

The third via hole 38G3 may be viewed as being formed in the form of a line passing through the first and second via holes 38G1 and 38G2 from one side of the second semiconductor layer 38 to the other. The first and second via holes 38G1 and 38G2 each may be viewed as that the width of the third via hole 38G3 at positions corresponding to the first and second via holes 38G1 and 38G2 are widened (expanded) in a direction perpendicular (y-axis direction) to the longitudinal direction (x-axis direction) of the third via hole 38G3.

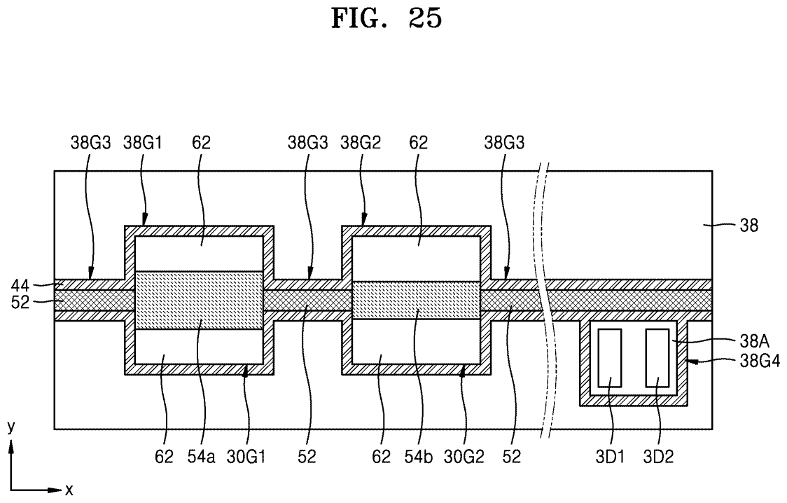

According to one or more example embodiments, in FIG. 5A, the fourth via hole 38G4 may not be formed at the right end of the third via hole 38G3 but may be formed below or above the third via hole 38G3. In this case, as will be described later, the light receiving element 53 may not be formed close to one end (e.g., right end) of the waveguide, but may be formed adjacent to a side of the waveguide below or above the waveguide as illustrated according to an embodiment in FIG. 25.

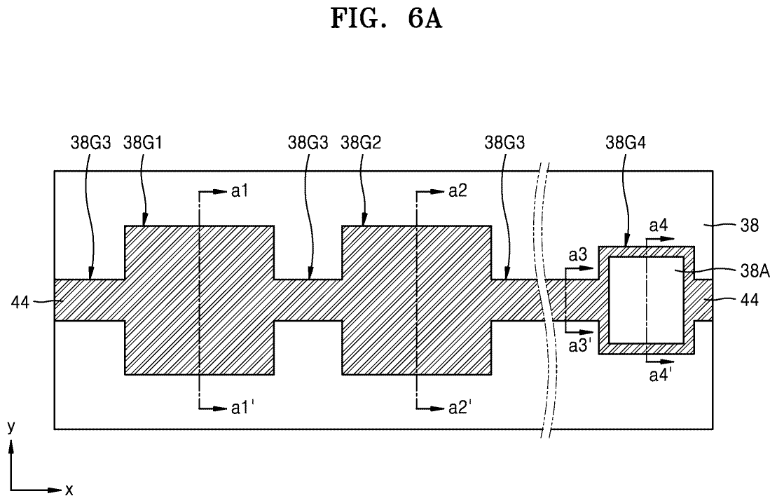

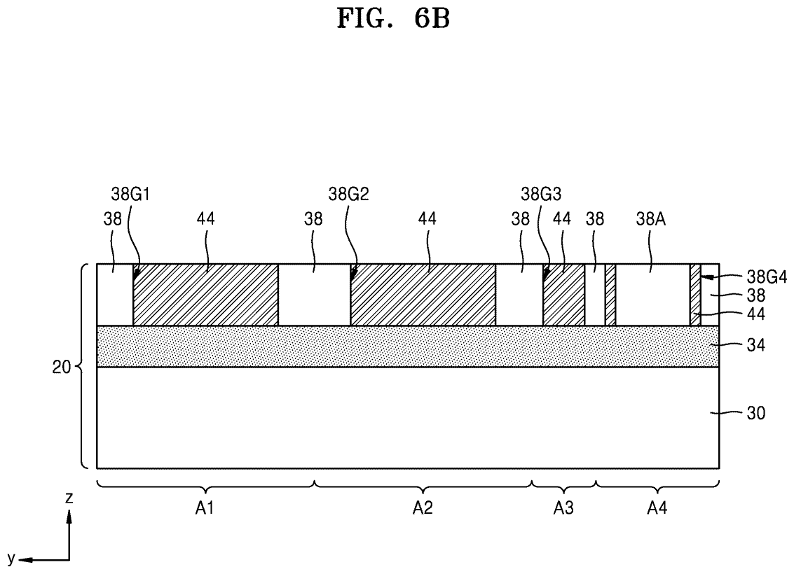

Next, as shown in FIGS. 6A and 6B, the first to fourth via holes 38G1 to 38G4 are filled with a second insulating layer 44. The first to fourth via holes 38G1 to 38G4 may be completely filled with the second insulating layer 44. For example, after forming the second insulating layer 44 to fill the first to fourth via holes 38G1 to 38G4 on the second semiconductor layer 38, a planarization process may be performed on the second insulating layer 44 using CMP or the like, and the planarization process may be performed until the upper surface of the second semiconductor layer 38 is exposed.

According to one or more example embodiments, a material of the second insulating layer 44 may be the same as a material of the first insulating layer 34, but the disclosure is not limited thereto. According to one or more example embodiments, the first and second insulating layers 34 and 44 may include different insulating materials or dielectric materials.

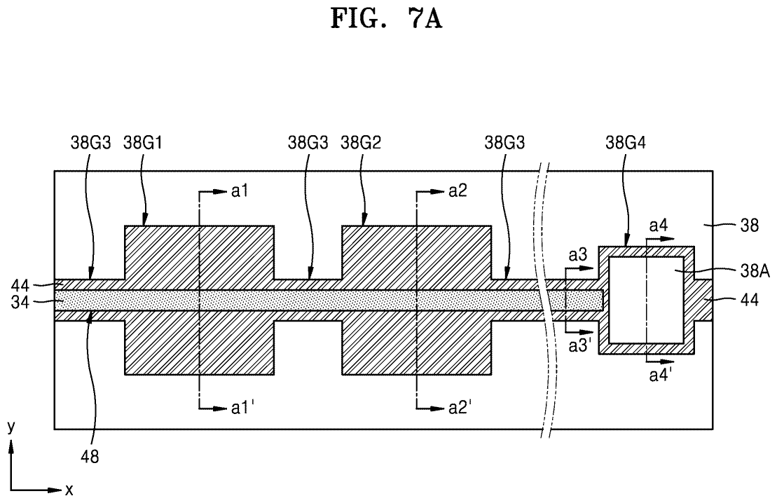

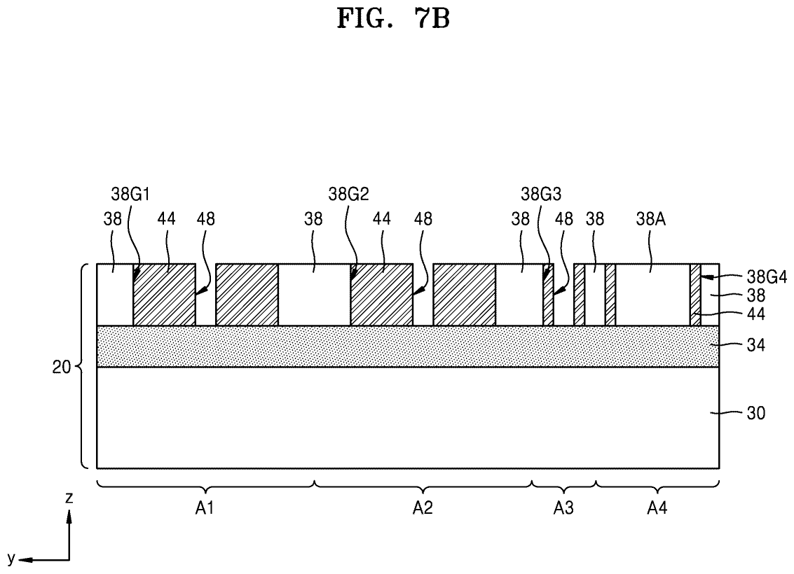

Next, as shown in FIGS. 7A and 7B, a fifth via hole 48 is formed in the second insulating layer 44. For example, the first via hole 48 may be configured to expose the first insulating layer 34. The fifth via hole 48 may be formed through a photoetching process, but the disclosure is not limited to this. Because the fifth via hole 48 is for forming a waveguide, it may be expressed as a waveguide via hole. From the view of the substrate 20, the fifth via hole 48 may be regarded as a trench or groove formed in the substrate 20, and therefore, considering its purpose, the fifth via hole 48 may be expressed as a waveguide trench.

According to an embodiment, the fifth via hole 48 is for forming a waveguide, and as such, the fifth hole 48 may be formed along the third via hole 38G3. That is, the fifth via hole 48 may be formed parallel to the third via hole 38G3. Accordingly, the fifth via hole 48 may be formed in a line shape having the same or substantially the same length as the third via hole 38G3. The fifth via hole 48 may be formed to be spaced apart from an inner wall or inner side of the first to fourth via holes 38G1 to 38G4. The fifth via hole 48 may be formed to be spaced apart from the first pattern 38A. However, the fifth via hole 48 may be formed close to the first pattern 38A so that light leaking from the waveguide (e.g., evanescent wave) may reach the first pattern 38A.

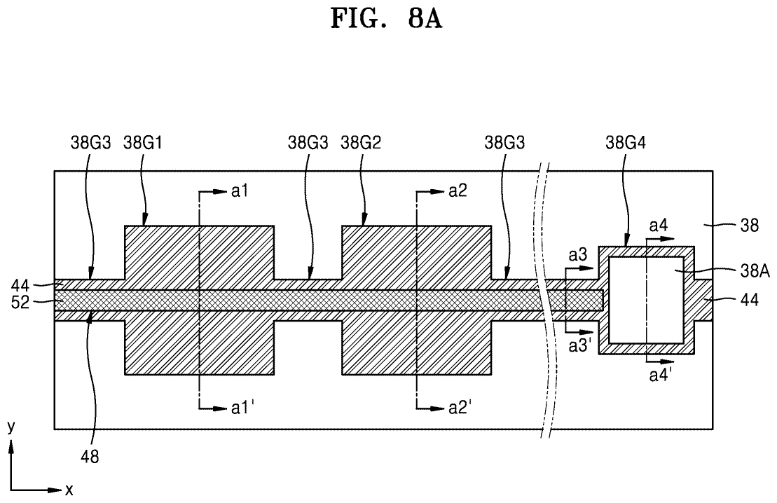

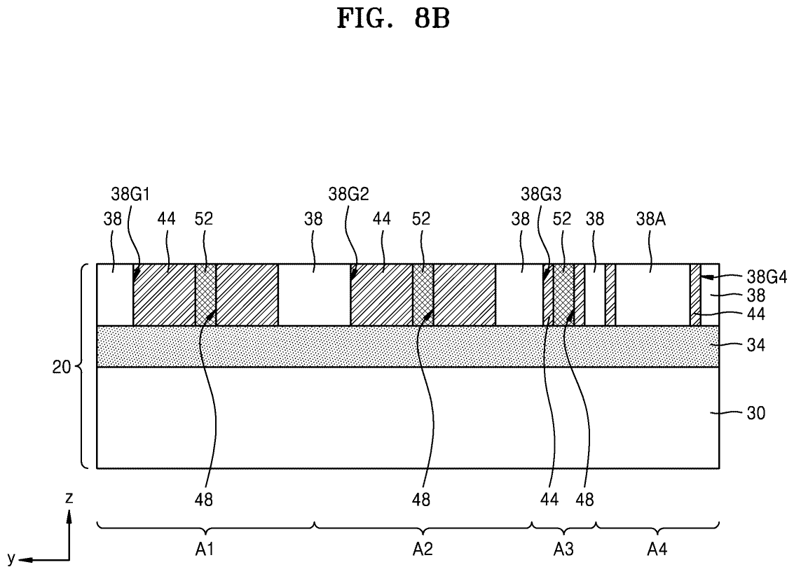

Next, as shown in FIGS. 8A and 8B, the fifth via hole 48 is completely filled with a waveguide material layer 52. The waveguide material layer 52 is a material layer to be used as an optical waveguide and may be used to transmit light in the visible light band, but the disclosure is not limited thereto. According to one or more example embodiments, the waveguide material layer 52 may be used to transmit light of a wavelength in a range from about 400 nm to about 500 nm, but the disclosure is not limited to light of this wavelength. According to one or more example embodiments, the waveguide material layer 52 may include, but the disclosure is not limited to, silicon nitride or titanium oxide.

The waveguide material layer 52 that fills the fifth via hole 48 may be formed by performing a planarizing process on the waveguide material layer 52 after forming the waveguide material layer 52 that fills the fifth via hole 48 on the second insulating layer 44. The planarization process may be performed until the second insulating layer 44 is exposed.

According to an embodiment, the waveguide material layer 52 may completely fill the fifth via hole 48, and as such, a height of the waveguide material layer 52 may be equal to or substantially equal to a height of the second insulating layer 44 and a height of the second semiconductor layer 38.

Hereinafter, the waveguide material layer 52 is referred to as the waveguide 52.

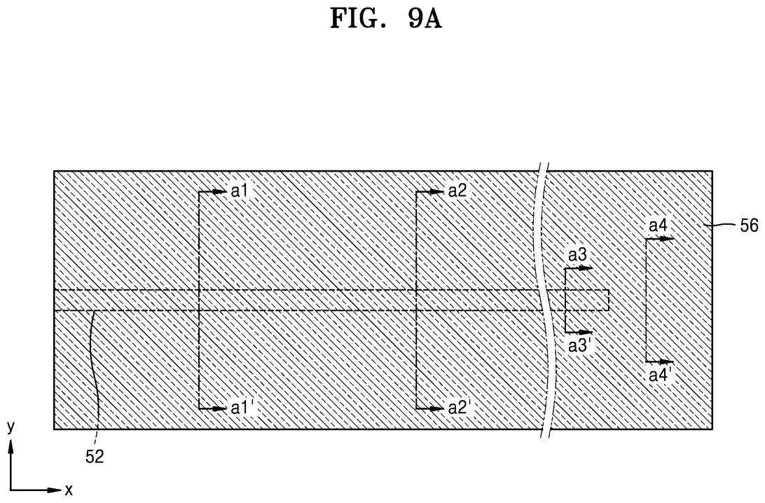

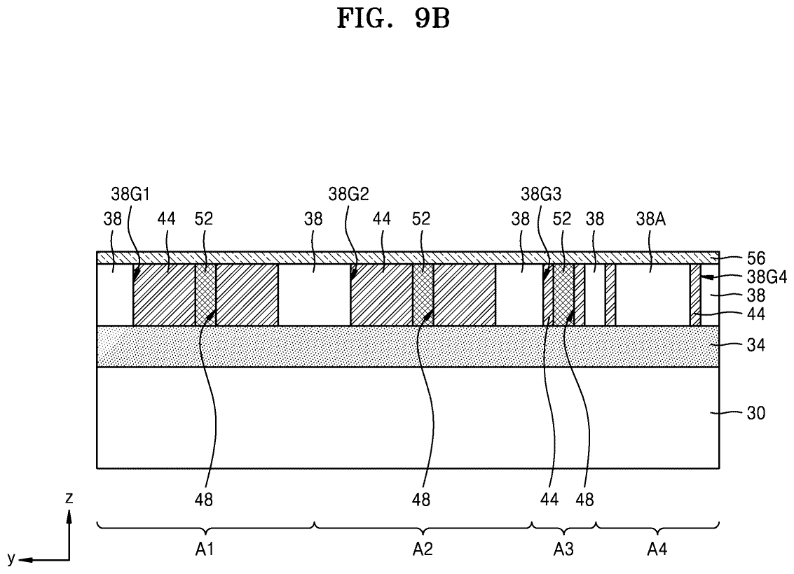

As shown in FIGS. 9A and 9B, after forming the waveguide 52, a third insulating layer 56 covering the waveguide 52 and the second insulating layer 44 may be formed on an upper surface of the second semiconductor layer 38. The third insulating layer 56 may be formed to cover the entire upper surface of the second semiconductor layer 38, and may be formed to cover an entire upper surface of the waveguide 52 and an entire upper surface of the second insulating layer 44. The third insulating layer 56 may be formed to directly contact the second semiconductor layer 38, the waveguide 52, and the second insulating layer 44, but the disclosure is not limited thereto. After forming the third insulating layer 56, a planarization operation may be performed on an upper surface of the third insulating layer 56. Accordingly, the upper surface of the third insulating layer 56 may be entirely flat.

According to one or more example embodiments, the third insulating layer 56 may include the same material as the second insulating layer 44 but may also include a different material from the second insulating layer 44.

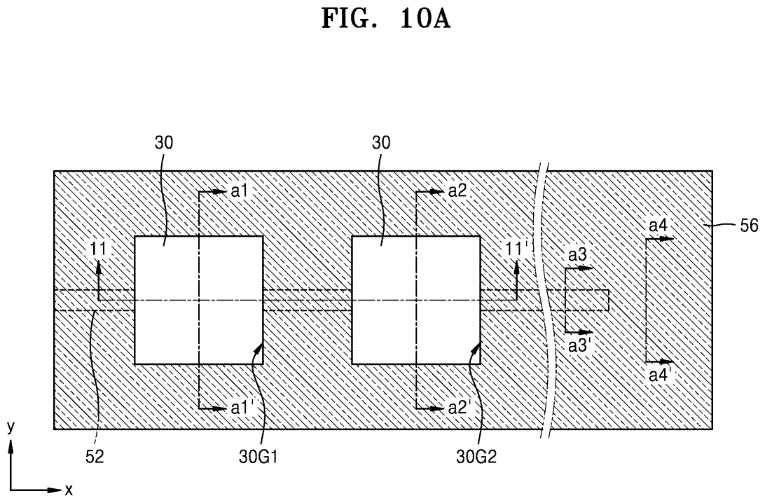

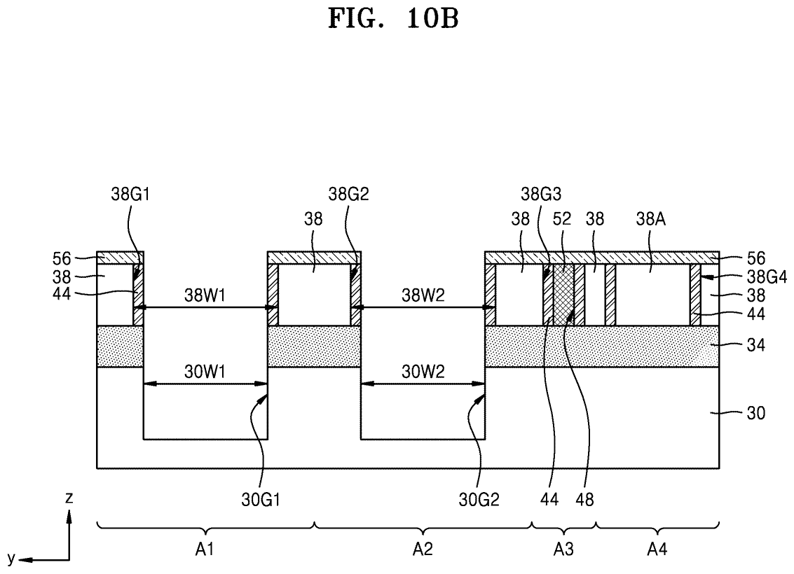

Next, as shown in FIGS. 10A and 10B, a first groove 30G1 is formed in the first via hole 38G1, and a second groove 30G2 is formed in the second via hole 38G2. According to an embodiment, a light source may be formed in the first groove 30G1 and a light modulator may be formed in the second groove 30G2. However, the disclosure in not limited thereto, and as such, according to another embodiment, the light source may be formed in the second groove 30G2 and the light modulator may be formed in the first groove 30G1. In another embodiment, other components may be provided in the first groove 30G1 and or the second grove G2. A width 30W1 of the first groove 30G1 in a direction perpendicular to a length of the waveguide 52 (y-axis direction) may be less than a width 38W1 of the first via hole 38G1 in the same direction. A width 30W2 of the second groove 30G2 in a direction perpendicular to the length of the waveguide 52 may be less than a width 38W2 of the second via hole 38G2 in the same direction.

The width 30W1 of the first groove 30G1 may be the same or substantially the same as the width 30W2 of the second groove 30G2, and the two widths 30W1 and 30W2 may be different from each other. The width 38W1 of the first via hole 38G1 may be the same or substantially the same as the width 38W2 of the second via hole 38G2, and the two widths 38W1 and 38W2 may be different from each other.

According to an embodiment, the width 38W1 of the first via hole 38G1 and the width 30W1 of the first groove 30G1 are different from each other, and as such, a step difference may be formed between the first via hole 38G1 and the first groove 30G1. In addition, the width 38W2 of the second via hole 38G2 and the width 30W2 of the second groove 30G2 are different from each other, and as such, a step difference may be formed between the second via hole 38G2 and the second groove 30G2.

According to one or more example embodiments, the first groove 30G1 and the second groove 30G2 may be formed simultaneously. Accordingly, the first groove 30G1 and the second groove 30G2 may be formed to the same or substantially the same depth. According to one or more example embodiments, the first groove 30G1 and the second groove 30G2 may be formed to have a size in a range from about 3 μm to about 8 μm but are not limited thereto.

In an etching process to form the first and second grooves 30G1 and 30G2, portions corresponding to the first and second grooves 30G1 and 30G2 of the waveguide 52 may be removed. The etching process may include, but the disclosure is not limited to, dry etching.

As the first and second grooves 30G1 and 30G2 are formed, the waveguide 52 may be cut or separated into several parts and may be a shape provided on both sides of the first groove 30G1 and on both sides of the second groove 30G2. As the first and second grooves 30G1 and 30G2 are formed, side surfaces of the waveguide 52 may be exposed laterally through side surfaces of the first and second grooves 30G1 and 30G2. That is, the side surfaces of the waveguide 52 that is cut off as the first and second grooves 30G1 and 30G2 are formed may become side walls or a part of the side walls of the first and second grooves 30G1 and 30G2. In other words, the side surfaces of the waveguide 52 that is cut off as the first and second grooves 30G1 and 30G2 are formed may form the same plane (side surface, side wall) as the side surfaces of the first and second grooves 30G1 and 30G2.

The first and second grooves 30G1 and 30G2 may be formed to penetrate the first insulating layer 34 and then extend into the first semiconductor layer 30 at a given depth. Accordingly, the first semiconductor layer 30 may be exposed through the first and second grooves 30G1 and 30G2. That is, parts of the side surfaces and lower surfaces of the first and second grooves 30G1 and 30G2 may become the first semiconductor layer 30.

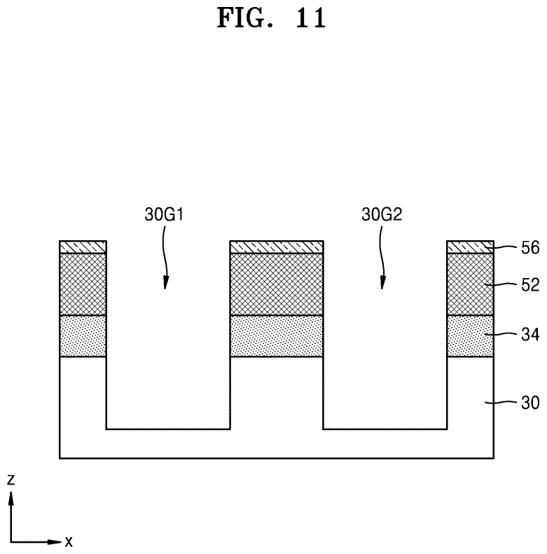

Referring to FIGS. 10A, 10B, and FIG. 11 showing a cross-sectional view taken along line 11-11′ of FIG. 10A, the remaining side surfaces of the first and second grooves 30G1 and 30G2 may be the first insulating layer 34, the second insulating layer 44, the waveguide 52, and the third insulating layer 56.

As a result, the inner side surfaces of each of the first and second grooves 30G1 and 30G2 may be formed as the side surface of a plurality of material layers 30, 34, 44, 52, and 56. For example, the side surfaces of the lower layer of the first and second grooves 30G1 and 30G2 may include the side surface of the first semiconductor layer 30, the side surfaces of the middle layer of the first and second grooves 30G1 and 30G2 may include the side surface of the first insulating layer 34, and the side surfaces of the upper layer of the first and second grooves 30G1 and 30G2 may include the side surfaces of the second insulating layers 44, the waveguide 52, and the third insulating layer 56.

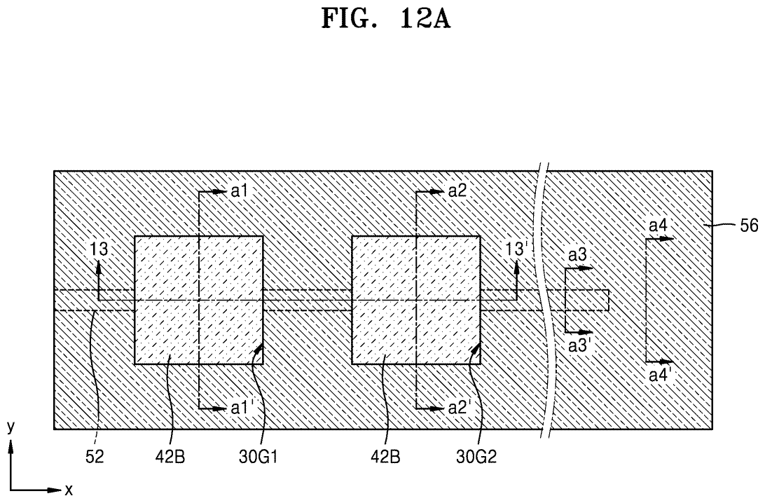

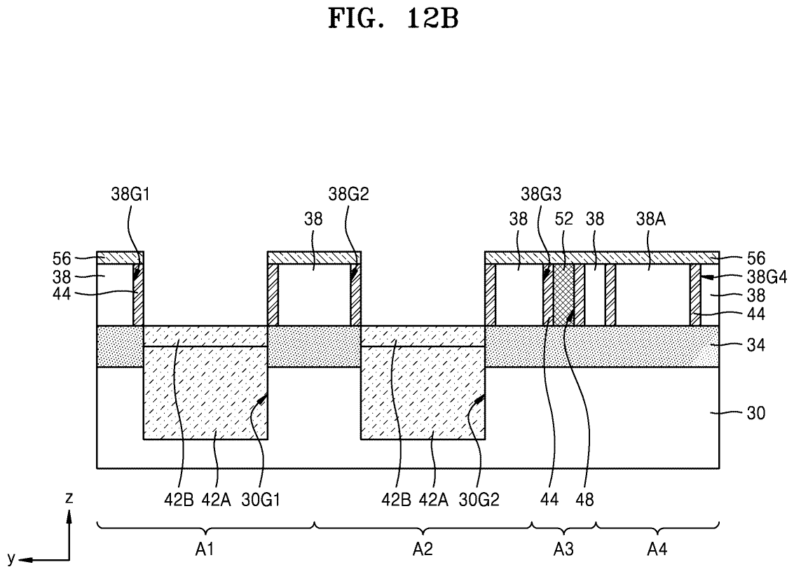

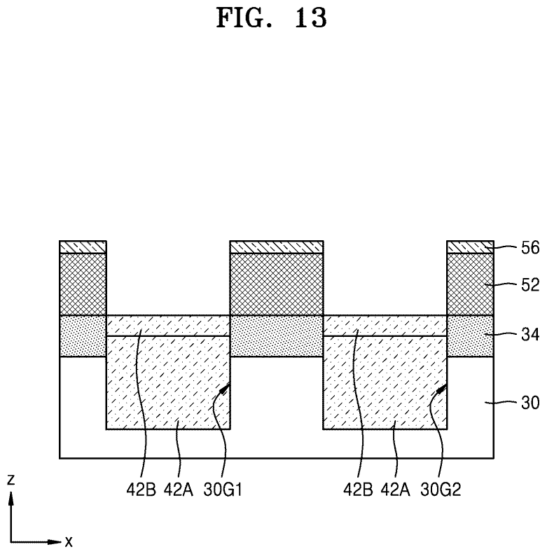

Next, referring to FIGS. 12A, 12B, and FIG. 13 showing a cross-sectional view taken along line 13-13′ of FIG. 12A, a buffer layer 42A and a first compound semiconductor layer 42B may be provided in the first and second grooves 30G1 and 30G2. For example, the buffer layer 42A and the first compound semiconductor layer 42B may be sequentially formed in each of the first and second grooves 30G1 and 30G2 to fill a portion of the first groove 30G1 and a portion of the second groove 30G2. According to one or more example embodiments, a height of the first compound semiconductor layer 42B may be the same or substantially the same as the height of the first insulating layer 34. According to one or more example embodiments, the height of the first compound semiconductor layer 42B may be formed to be slightly less than the height of the upper surface of the first insulating layer 34. In other words, the height of the upper surface of the first compound semiconductor layer 42B may be slightly less than the height of a lower surface of the waveguide 52. As a result, the first compound semiconductor layer 42B and the waveguide 52 may not be in direct contact.

According to one or more example embodiments, the buffer layer 42A and the first compound semiconductor layer 42B may be formed by using a growth method, for example, by using a selective heteroepitaxy method but are not limited thereto. The growth method may be a high temperature process conducted at 500° C. or higher or 600° C. or higher.

The buffer layer 42A may be formed to have a thickness greater than a thickness of the first compound semiconductor layer 42B. For example, a height of the buffer layer 42A may be greater than a height of the first semiconductor layer 30.

Although a boundary between the buffer layer 42A and the first compound semiconductor layer 42B is clearly shown in FIG. 12B, because the buffer layer 42A and the first compound semiconductor layer 42B are grown by a growth method and the growth may be performed continuously, the boundary between the buffer layer 42A and the first compound semiconductor layer 42B may not be clear or may not be distinguished with the naked eye as shown in FIG. 12. In particular, in an example case in which a basic composition of an upper layer of the buffer layer 42A, that is, the basic composition of a portion of the buffer layer 42A in contact with the first compound semiconductor layer 42B and a basic composition excluding the doping material (dopant) of the first compound semiconductor layer 42B are the same, the boundary may not exist as a physical boundary. For example, in a case in which the upper layer of the buffer layer 42A is an undoped GaN layer and the first compound semiconductor layer 42B is an n-type GaN layer, because the basic composition (GaN) of the upper layer of the buffer layer 42A and the basic composition (GaN) of the first compound semiconductor layer 42B are the same, the physical boundary between the buffer layer 42A and the first compound semiconductor layer 42B may not exist.

The side surfaces of the second semiconductor layer 38 are covered with the first insulating layer 44, and the upper surface of the second semiconductor layer 38 is covered with the third insulating layer 56. Therefore, while the buffer layer 42A and the first compound semiconductor layer 42B are formed by the above growth method, the buffer layer 42A and the first compound semiconductor layer 42B are not formed on the second semiconductor layer 38. In other words, while forming the buffer layer 42A and the first compound semiconductor layer 42B, the buffer layer 42A and the first compound semiconductor layer 42B are selectively formed only in the first and second grooves 30G1 and 30G2.

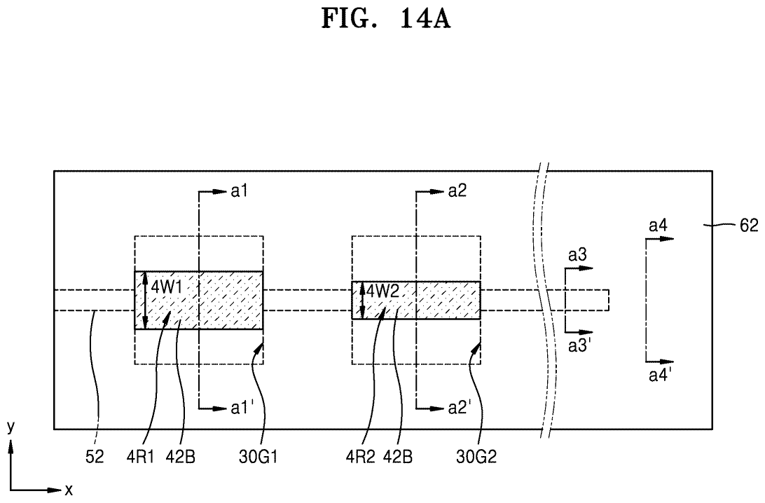

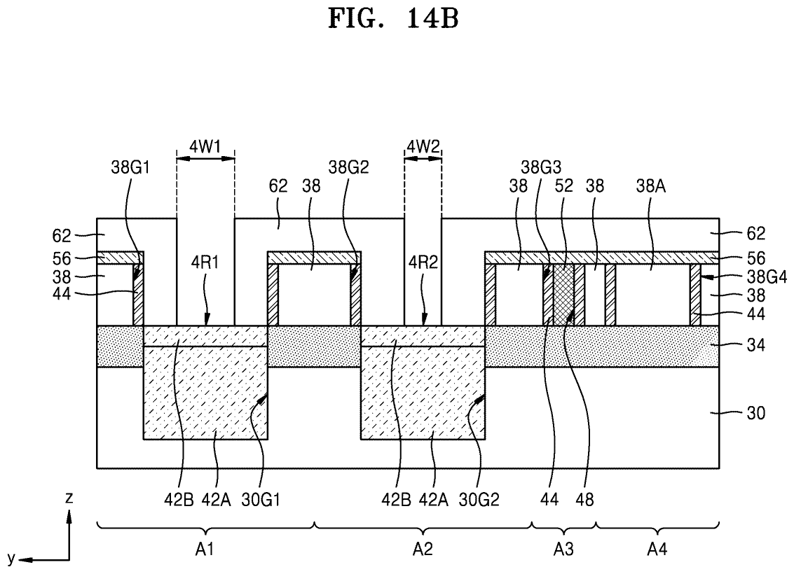

Next, as shown in FIGS. 14A and 14B, a fourth insulating layer 62 is formed on the third insulating layer 56. The fourth insulating layer 62 may be formed to cover the entire upper surface of the third insulating layer 56 and may be in direct contact with the corresponding upper surface of the third insulating layer 56. The fourth insulating layer 62 may also be formed on a partial region of the first compound semiconductor layer 42B within the first and second grooves 30G1 and 30G2. The fourth insulating layer 62 may be formed to cover a portion of an inner surface of the second insulating layer 44 and a portion of an inner surface of the third insulating layer 56, which are parts of the side surfaces of the first and second grooves 30G1 and 30G2. According to one or more example embodiments, a material (substance) of the fourth insulating layer 62 may be the same as one of the materials of the first to third insulating layers 34, 44, and 56, but the disclosure is not limited thereto. According to one or more example embodiments, the materials of the first to fourth insulating layers 34, 44, 56, and 62 may all be the same.

As shown in FIG. 14A, the fourth insulating layer 62 may be formed to define a first region 4R1 of the first compound semiconductor layer 42B in the first groove 30G1. In other words, the fourth insulating layer 62 may be formed to cover the entire upper surface of the first compound semiconductor layer 42B except for the first region 4R1. An active layer of a light-emitting device used as a light source may be formed on the first region 4R1.

A width of the first region 4R1 in the longitudinal direction (e.g., x-axis direction) of the waveguide 52 may be equal to a width of the first compound semiconductor layer 42B in the same direction. That is, the width of the first compound semiconductor layer 42B in the longitudinal direction of the waveguide 52 becomes the width of the first region 4R1 in the longitudinal direction of the waveguide 52.

For example, the first region 4R1 has a first width 4W1 in a direction perpendicular to the length of the waveguide 52 (e.g., y-axis direction). The first width 4W1 may be less than the width of the first compound semiconductor layer 42B in the same direction.

The fourth insulating layer 62 may be formed to define a second region 4R2 of the first compound semiconductor layer 42B in the second groove 30G2. In other words, the fourth insulating layer 62 may be formed to cover the entire upper surface of the first compound semiconductor layer 42B in the second groove 30G2 except for the second region 4R2. An active layer of a light modulator may be formed on the second region 4R2.

A width of the second region 4R2 in the length direction of the waveguide 52 in the second groove 30G2 may be equal to the width of the first compound semiconductor layer 42B in the same direction. That is, the width of the first compound semiconductor layer 42B in the longitudinal direction of the waveguide 52 becomes the width of the second region 4R2 in the longitudinal direction of the waveguide 52.

For example, the second region 4R2 has a second width 4W2 in a direction perpendicular to the length of the waveguide 52. The second width 4W2 may be less than the width of the first compound semiconductor layer 42B in the same direction.

The length (which may also be referred to as the width) of the first and second regions 4R1 and 4R2 in the longitudinal direction of the waveguide 52 may be the same or substantially the same but may also be different from each other.

The first width 4W1 and the second width 4W2 may be different from each other or may be the same. For example, the first width 4W1 may be greater than the second width 4W2.

An area of the first region 4R1 may be greater than an area of the second area 4R2, but the disclosure is not limited thereto.

The fourth insulating layer 62 defining the first and second regions 4R1 and 4R2 may be formed through the following process, but the disclosure is not limited thereto. That is, the fourth insulating layer 62 is formed on the third insulating layer 56 to completely fill the first and second grooves 30G1 and 30G2, and then, a mask defining the first and second regions 4R1 and 4R2 is formed on the fourth insulating layer 62 that fills the first and second grooves 30G1 and 30G2. Next, using the mask as an etch mask, the fourth insulating layer 62 is etched until the first compound semiconductor layer 42B is exposed, and then, the mask is removed.

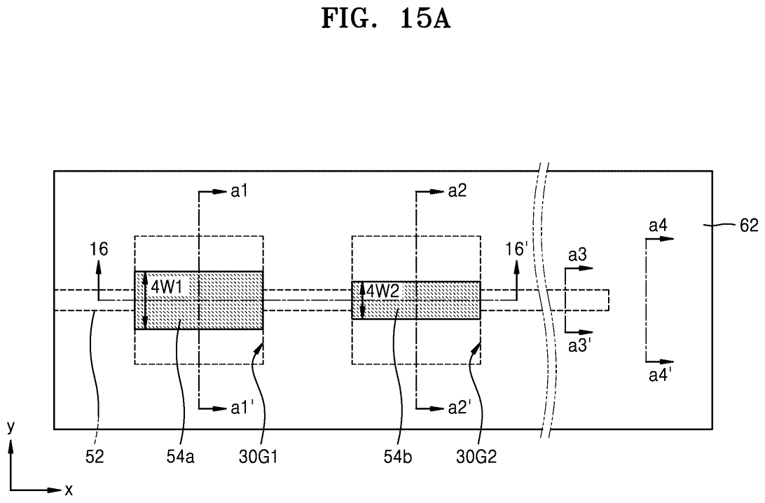

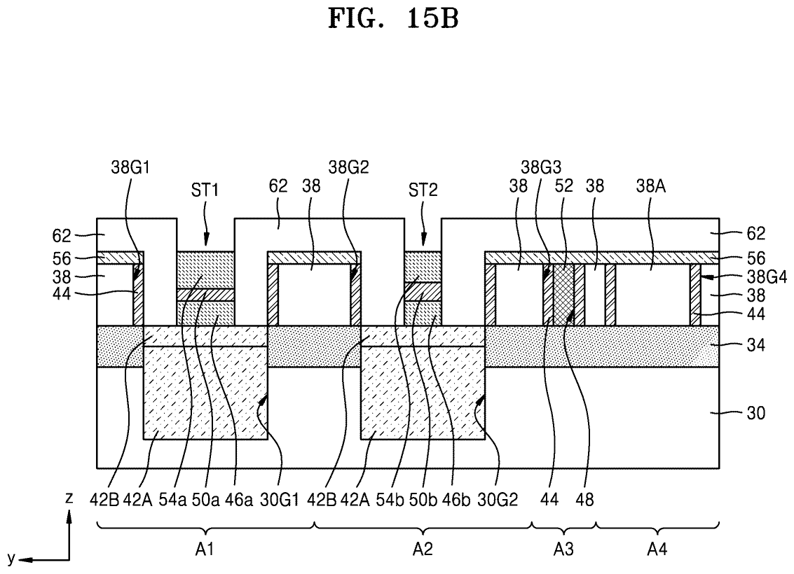

Next, as shown in FIGS. 15A and 15B, a second compound semiconductor layer 46a, a first active layer 50a, and a third compound semiconductor layer 54a may be provided in the first region 4R1 and a fourth compound semiconductor layer 46b, a second active layer 50b, and a fifth compound semiconductor layer 54b may be provided in the second region 4R2. For example, the second compound semiconductor layer 46a, the first active layer 50a, and the third compound semiconductor layer 54a may be sequentially formed on the first region 4R1 of the first compound semiconductor layer 42B in the first groove 30G1. For example, the fourth compound semiconductor layer 46b, the second active layer 50b, and the fifth compound semiconductor layer 54b are sequentially formed on the second region 4R2 of the first compound semiconductor layer 42B in the second groove 30G2. According to one or more example embodiments, a height of an upper surface of the first active layer 50a and a height of the second active layer 50b may be less than a height of an upper surface of the second semiconductor layer 38, but the disclosure is not limited thereto.

A process of forming the second compound semiconductor layer 46a, the first active layer 50a, and the third compound semiconductor layer 54a on the first region 4R1 of the first compound semiconductor layer 42B in the first groove 30G1 and a process of forming the fourth compound semiconductor layer 46b, the second active layer 50b, and the fifth compound semiconductor layer 54b on the second region 4R2 of the first compound semiconductor layer 42B in the second groove 30G2 may be simultaneously performed.

According to one or more example embodiments, the second compound semiconductor layer 46a, the first active layer 50a, and the third compound semiconductor layer 54a may be formed sequentially using a growth method, and the fourth compound semiconductor layer 46b, the second active layer 50b, and the fifth compound semiconductor layer 54b may also be formed sequentially using a growth method.

According to one or more example embodiments, an area of the first region 4R1 of the upper surface of the first compound semiconductor layer 42B in the first groove 30G1 and an area of the second region 4R2 on the upper surface of the first compound semiconductor layer 42B in the second groove 30G2 may be different from each other. Therefore, a speed at which the second compound semiconductor layer 46a, the first active layer 50a, and the third compound semiconductor layer 54a are formed on the first region 4R1 of the first groove 30G1 and a speed at which the fourth compound semiconductor layer 46b, the second active layer 50b, and the fifth compound semiconductor layer 54b are formed on the second region 4R2 of the second groove 30G2 may be different. However, a difference between the area of the first region 4R1 and the area of the second region 4R2 may be adjusted in an operation of forming the fourth insulating layer 62. Therefore, the difference in the formation speed, that is, the difference in the growth rate of the material layer between the first and second regions 4R1 and 4R2, may be so small as to be negligible.

According to one or more example embodiments, a thickness of a material layer formed in the second region 4R2, which has a relatively small area, may be greater than a thickness of a material layer formed in the first region 4R1. For example, the thickness of the first active layer 50a formed in the first region 4R1 may be less than the thickness of the second active layer 50b formed in the second region 4R2. For example, the thickness of the material layer formed in the second region 4R2 may be greater than the thickness of a material layer formed in the first region 4R1 due to the difference in formation speed or due to a control of the growth rate of the material layer formed in each region 4R1 and 4R2. For example, the difference in thicknesses of the material layers formed in the second region 4R2 and the first region 4R1 may be obtained by adjusting the time for forming the first active layer 50a in the first region 4R1 and the time for forming the second active layer 50b in the second region 4R2 the same, but the disclosure is not limited thereto.

According to one or more example embodiments, the third compound semiconductor layer 54a in the first region 4R1 may be formed at the same height as an upper surface of the fourth insulating layer 62, or lower or higher than the upper surface of the fourth insulating layer 62. For example, the third compound semiconductor layer 54a may be formed at the same height as the upper surface of the third insulating layer 56 or may be formed higher or lower than the third insulating layer 56.

According to one or more example embodiments, the height of the fifth compound semiconductor layer 54b in the second region 4R2 may be equal to, lower than, or higher than the height of the upper surface of the fourth insulating layer 62. For example, the height of the fifth compound semiconductor layer 54b may be equal to, lower than, or higher than the height of the upper surface of the third insulating layer 56.

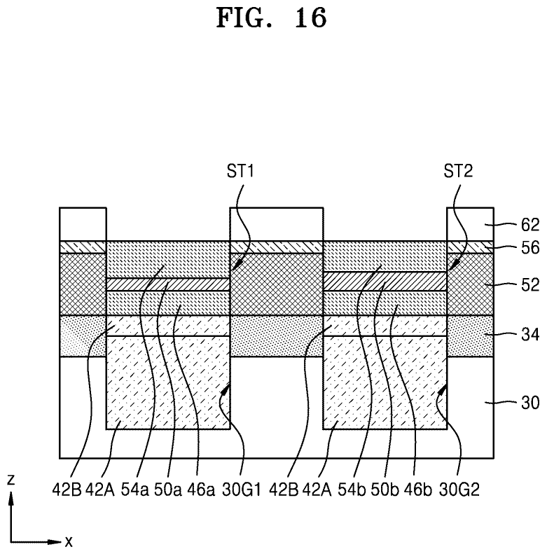

FIG. 16 shows a cross-sectional view taken along line 16-16′ of FIG. 15A. As shown in FIG. 16, side surfaces of the waveguide 52 is exposed through the first and second grooves 30G1 and 30G2. In other words, the side surfaces of the first and second grooves 30G1 and 30G2 include the side surfaces of the waveguide 52. Accordingly, at least the first active layer 50a and the waveguide 52 may be in direct contact with each other while forming the second compound semiconductor layer 46a, the first active layer 50a, and the third compound semiconductor layer 54a on the first region 4R1 of the first compound semiconductor layer 42B in the first groove 30G1. According to one or more example embodiments, the second compound semiconductor layer 46a, the first active layer 50a, and the third compound semiconductor layer 54a may all be in direct contact with the waveguide 52. Accordingly, light generated and emitted from the first active layer 50a may be directly focused into the waveguide 52, and thus, reflection of light from the waveguide 52 may be prevented or minimized in the process of focusing the light into the waveguide 52. The light generated in the first active layer 50a may be emitted in at least one of the right and left directions of the first active layer 50a, but the disclosure is not limited to this.

Also, at least the second active layer 50b and the waveguide 52 may be in direct contact with each other while forming the fourth compound semiconductor layer 46b, the second active layer 50b, and the fifth compound semiconductor layer 54b on the second region 4R2 of the first compound semiconductor layer 42B in the second groove 30G2. According to one or more example embodiments, the fourth compound semiconductor layer 46b, the second active layer 50b, and the fifth compound semiconductor layer 54b may all be in direct contact with the waveguide 52. Therefore, modulated or unmodulated light generated and emitted from the second active layer 50b may be directly focused into the waveguide 52, and thus, reflection of light from the waveguide 52 may be prevented or minimized in this process. Light generated in the second active layer 50b may be emitted in a direction opposite to a direction in which the first active layer 50a is located.

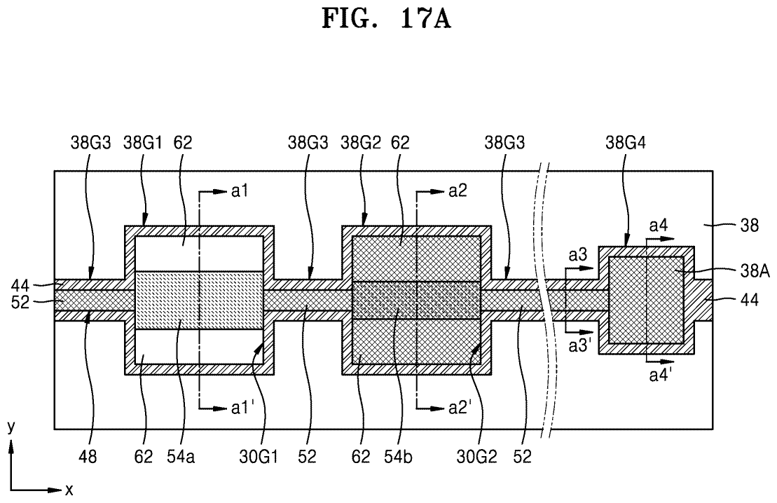

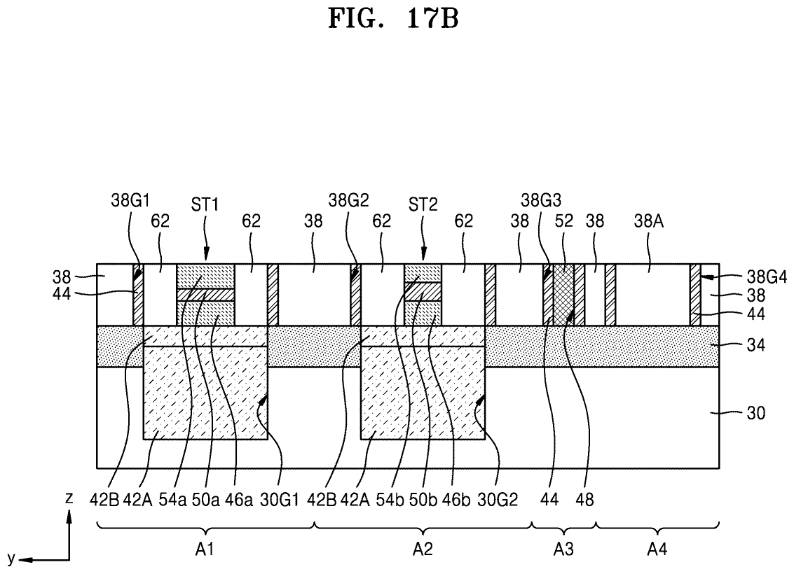

As shown in FIGS. 17A and 17B, the second compound semiconductor layer 46a, the first active layer 50a, and the third compound semiconductor layer 54a are sequentially formed on the first region 4R1 to form a first layer structure ST1, and the second compound semiconductor layer 46b, the second active layer 50b, and the fifth compound semiconductor layer 54b are sequentially formed on the second region 4R2 to form a second layer structure ST2, and then, the fourth insulating layer 62 and the third insulating layer 56 may be sequentially removed. According to one or more example embodiments, the removal of the fourth insulating layer 62 and the third insulating layer 56 may be performed using a dry etching method or a planarization process, but the disclosure is not limited thereto. The etching process or planarization process to remove the fourth insulating layer 62 and the third insulating layer 56 may be performed until the waveguide 52 is exposed. In this process, a portion of the third compound semiconductor layer 54a and/or the fifth compound semiconductor layer 54b may also be removed. A surface from which the fourth insulating layer 62, the third insulating layer 56, the third compound semiconductor layer 54a, and/or the fifth compound semiconductor layer 54b has been removed may be flat.

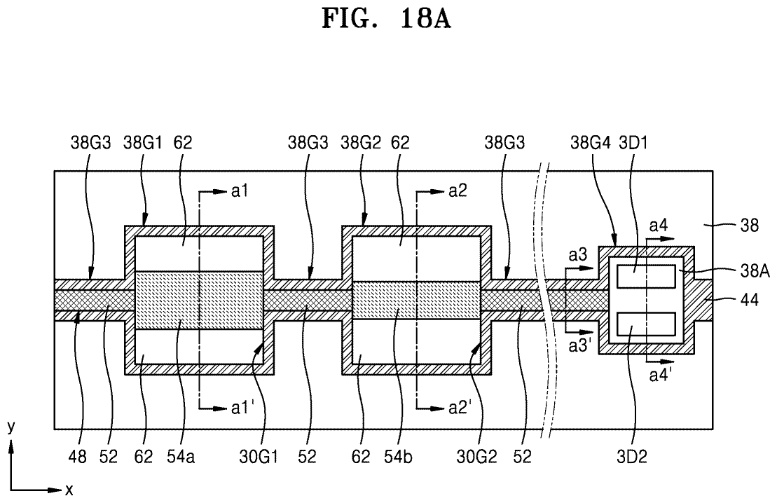

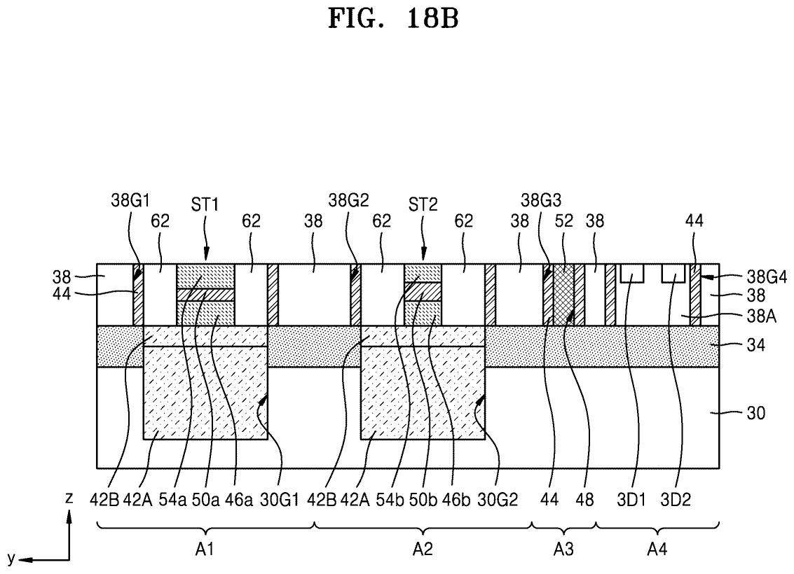

Next, as shown in FIGS. 18A and 18B, first and second doped layers 3D1 and 3D2 spaced apart from each other may be formed on the first pattern 38A of the second semiconductor layer 38. According to one or more example embodiments, the first and second doped layers 3D1 and 3D2 may be spaced apart from a bottom of the first pattern 38A. A region between the first and second doped layers 3D1 and 3D2 in the first pattern 38A may be a channel through which photocurrent flows.

The first doped layer 3D1 may be formed by injecting a first dopant into the corresponding region, and the second doping layer 3D2 may be formed by injecting a second dopant into the corresponding region. According to one or more example embodiments, the first and second dopants may be implanted using an ion implantation method, but the method is not limited thereto. One of the first and second dopants may include a p-type dopant (e.g., a Group III element), and the other may include an n-type dopant (e.g., a Group V element). The first pattern 38A on which the first and second doped layers 3D1 and 3D2 are formed may function as a photodiode, which is one of light receiving elements.

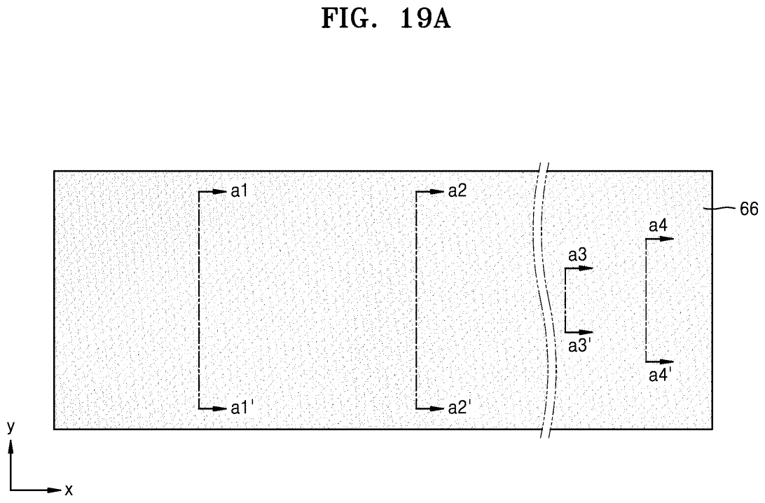

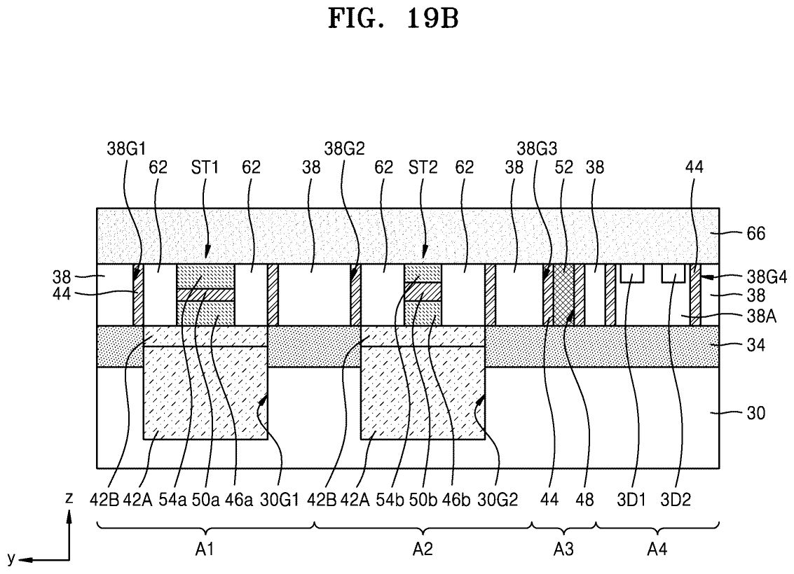

As shown in FIGS. 19A and 19B, after forming the first and second doped layers 3D1 and 3D2, a fifth insulating layer 66 may be formed on the upper surface of the second semiconductor layer 38. The fifth insulating layer 66 may be formed to cover the second insulating layer 44, the fourth insulating layer 62, the third compound semiconductor layer 54a, the fifth compound semiconductor layer 54b, the waveguide 52, the first doped layer 3D1, the second doped layer 3D2, and the first pattern 38A. The fifth insulating layer 66 may be in direct contact with the entire upper surfaces of the second semiconductor layer 38, the second insulating layer 44, the fourth insulating layer 62, the third compound semiconductor layer 54a, the fifth compound semiconductor layer 54b, the waveguide 52, the first doped layer 3D1, the second doped layer 3D2, and the first pattern 38A, but the disclosure is not limited thereto. According to one or more example embodiments, a material of the fifth insulating layer 66 may be the same as one of the first to fourth insulating layers 34, 44, 56, and 62, but the disclosure is not limited thereto.

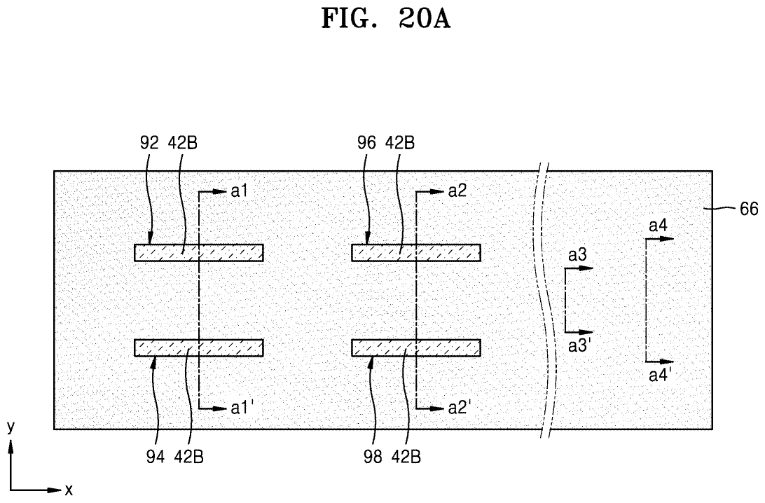

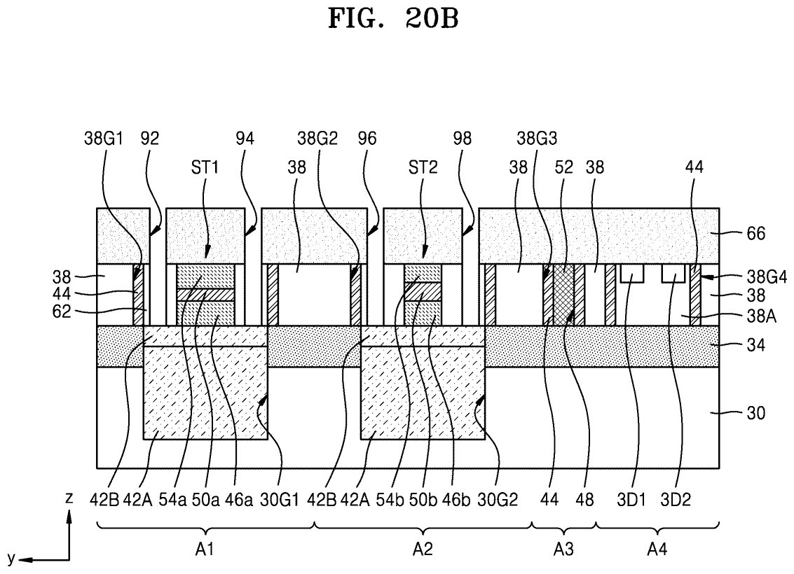

Next, as shown in FIGS. 20A and 20B, ninth and tenth through holes 92 and 94 may be formed in a region corresponding to the first groove 30G1 of the fifth insulating layer 66, and eleventh and twelfth through holes 96 and 98 may be formed in a region corresponding to the second groove 30G2.

The ninth and tenth through holes 92 and 94 may be formed on both sides of the first layer structure ST1, respectively, and the eleventh and twelfth through holes 96 and 98 may be formed on both sides of the second layer structure ST2. The ninth to twelfth through holes 92, 94, 96, and 98 are all formed to penetrate the fifth insulating layer 66 and the fourth insulating layer 62. Accordingly, the first compound semiconductor layer 42B of the first groove 30G1 may be exposed through the ninth and tenth through-holes 92 and 94, and the first compound semiconductor layer 42B of the second groove 30G2 may be exposed through the eleventh and twelfth through holes 96 and 98.

The ninth and tenth through holes 92 and 94 may be spaced apart from the first layer structure ST1 and the second semiconductor layer 38. The eleventh and twelfth through holes 96 and 98 may be spaced apart from the second layer structure ST2 and the second semiconductor layer 38.

According to one or more example embodiments, the ninth to twelfth through holes 92, 94, 96, and 98 may all be formed simultaneously using a first forming method. According to one or more example embodiments, the first forming method may include an etching process. As an example, the etching process may include a dry etching process, and may include etching, such as sputter etching using sputtering, reactive ion etching, chemical vapor deposition (CVD) method (e.g., Metal Organic CVD (MOCVD)), etc., but are not limited thereto.

According to one or more example embodiments, diameters (widths) of the ninth to twelfth through holes 92, 94, 96, and 98 may be the same, but may also be different.

According to one or more example embodiments, a first metal thin film for ohmic contact may be formed on a surface of the first compound semiconductor layer 42B exposed through the ninth to twelfth through holes 92, 94, 96, and 98. The thickness of the first metal thin film is not shown in the drawing because it is very thin.

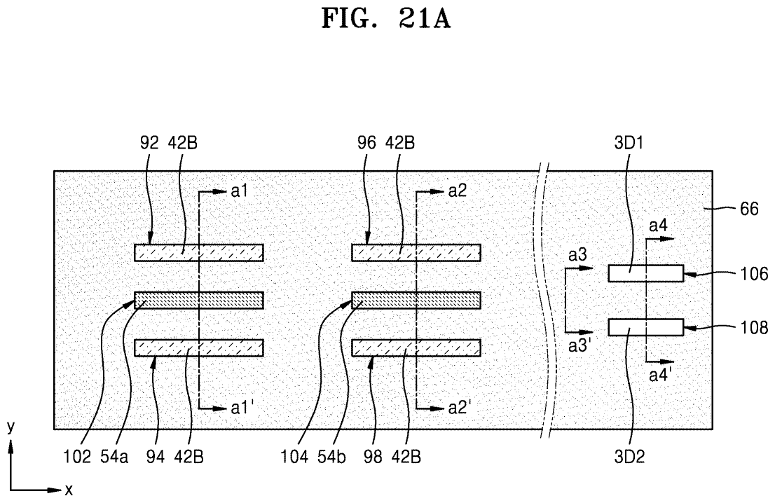

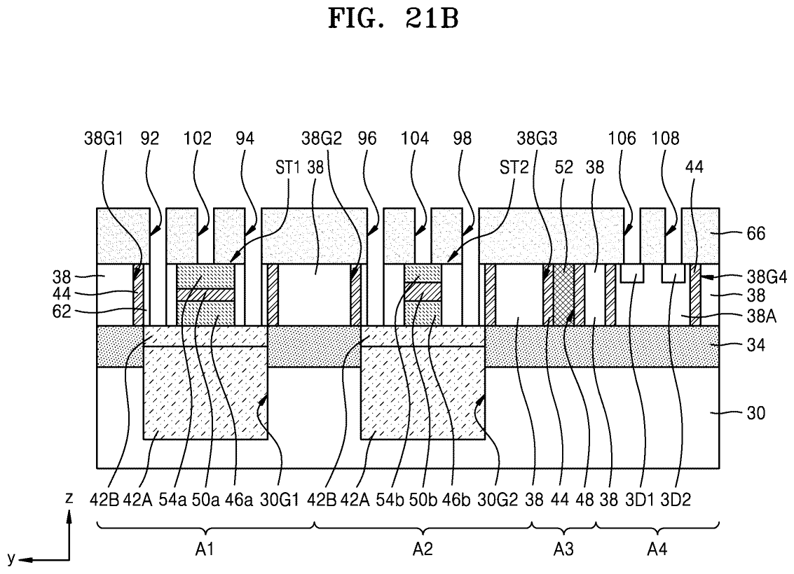

Next, as shown in FIGS. 21A and 21B, a thirteenth through hole 102 may be formed in a region corresponding to the first layer structure ST1 of the fifth insulating layer 66, a fourteenth through hole 104 may be formed in a region corresponding to the second layer structure ST2, a fifteenth through hole 106 may be formed in a region corresponding to the first doped layer 3D1 of the fifth insulating layer 66, and a sixteenth through hole 108 may be formed in a region corresponding to the second doped layer 3D2. Depths of the thirteenth to sixteenth through holes 102, 104, 106, and 108 may be less than depths of the ninth to twelfth through holes 92, 94, 96, and 98.

The thirteenth through hole 102 is located between the ninth and tenth through holes 92 and 94 and is located on the third compound semiconductor layer 54a. The thirteenth through hole 102 is formed to penetrate the fifth insulating layer 66. Accordingly, the third compound semiconductor layer 54a may be exposed through the thirteenth through hole 102.

The fourteenth through hole 104 is located between the eleventh and twelfth through holes 96 and 98, and is located on the fifth compound semiconductor layer 54b. The fourteenth through hole 104 is formed to penetrate the fifth insulating layer 66. Accordingly, the fifth compound semiconductor layer 54b may be exposed through the fourteenth through hole 104.

The fifteenth through hole 106 is located on the first doped layer 3D1 and is formed to penetrate the fifth insulating layer 66. Accordingly, the first doped layer 3D1 is exposed through the fifteenth through hole 106. The sixteenth through hole 108 is located on the second doped layer 3D2 and is formed to penetrate the fifth insulating layer 66. Accordingly, the second doped layer 3D2 is exposed through the sixteenth through hole 108.

The thirteenth to sixteenth through holes 102, 104, 106, and 108 may be formed simultaneously using the first forming method.

For example, diameters of the thirteenth to sixteenth through holes 102, 104, 106, and 108 may be the same or different from each other. The diameters of the thirteenth to sixteenth through holes 102, 104, 106, and 108 may be the same as or different from the diameters of the ninth to twelfth through holes 92, 94, 96, and 98.

According to one or more example embodiments, a second metal thin film for forming ohmic contact may be formed on a surface of the third compound semiconductor layer 54a exposed through the thirteenth through hole 102 and a surface of the fifth compound semiconductor layer 54b exposed through the fourteenth through hole 104.

According to one or more example embodiments, a third metal thin film for forming ohmic contact may be formed on a surface of the first doped layer 3D1 exposed through the fifteenth through hole 106 and a surface of the second doped layer 3D2 exposed through the sixteenth through hole 108. According to one or more example embodiments, materials of the second and third metal thin films may be the same.

In an example case in which the materials of the second and third metal thin films are different from each other, after the operation shown in FIG. 20, the thirteenth and fourteenth through holes 102 and 104 and the fifteenth and sixteenth through holes 106 and 108 may not be formed simultaneously, but may be formed at a time lag. For example, the thirteenth and fourteenth through holes 102 and 104 are first formed, the second metal thin film may be formed, then the fifteenth and sixteenth through holes 106 and 108 are formed, and the third metal thin film may be formed. According to one or more example embodiments, the fifteenth and sixteenth through holes 106 and 108 and the third metal thin film may be formed before the thirteenth and fourteenth through holes 102 and 104 and the second metal thin film.

Thicknesses of the second and third metal thin films are not shown in the drawing because they are very thin.

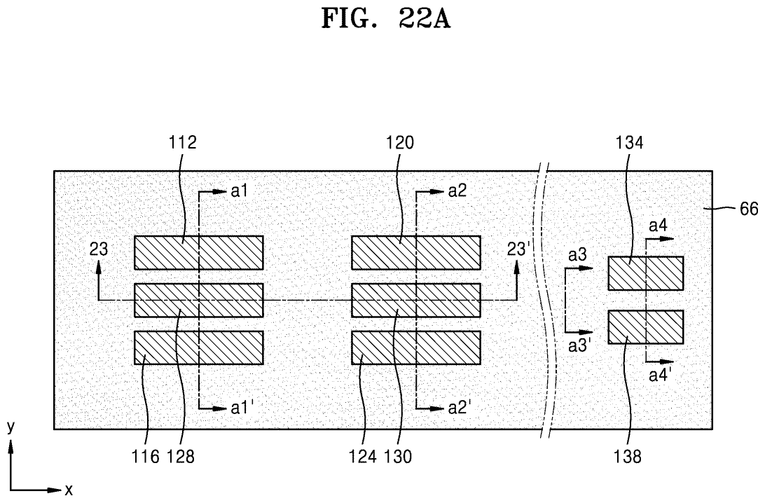

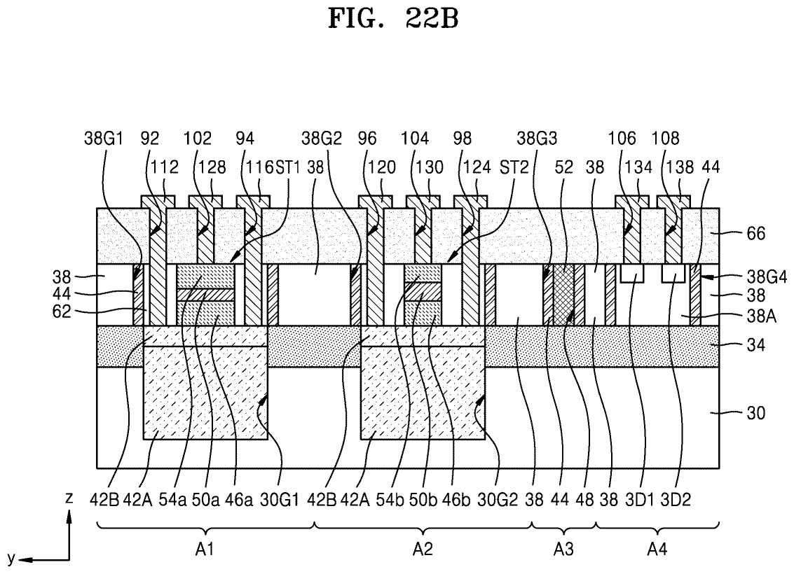

Next, as shown in FIGS. 22A and 22B, a ninth electrode (layer) 112 that fills the ninth through hole 92, a tenth electrode (layer) 116 that fills the tenth through hole 94, an eleventh electrode (layer) 120 that fills the eleventh through hole 96, (layer) 120, a twelfth electrode (layer) 124 that fills the twelfth through hole 98 may be formed on the fifth insulating layer 66, and a thirteenth electrode (layer) 128 that fills the thirteenth through hole 102, a fourteenth electrode (layer) 130 that fills the fourteenth through hole 104, a fifteenth electrode (layer) 134 that fills the fifteenth through hole 106 and sixteenth electrode (layer) 138 that fills the sixteenth through hole 108 may be formed. Each of the ninth to sixteenth electrodes (layers) 112, 116, 120, 124, 128, 130, 134, and 138 may completely fill each of the corresponding ninth to sixteenth through holes 92, 94, 96, 98, 102, 104, 106, and 108. Therefore, the ninth, tenth, eleventh, and twelfth electrodes (layers) 112, 116, 120, and 124 may be in direct contact with the first compound semiconductor layer 42B or are connected to the first compound semiconductor layer 42B through a metal thin film for ohmic contact. The thirteenth electrode 128 may be in direct contact with the third compound semiconductor layer 54a or may be in contact with the third compound semiconductor layer 54a through a metal thin film for ohmic contact. The fourteenth electrode (layer) 130 may be in direct contact with the fifth compound semiconductor layer 54b or may be in contact with the fifth compound semiconductor layer 54b through a metal thin film for ohmic contact. The fifteenth electrode (layer) 134 may be in direct contact with the first doped layer 3D1 or may be in contact with the first doped layer 3D1 through a metal thin film for ohmic contact. The sixteenth electrode (layer) 138 may be in direct contact with the second doped layer 3D2 or may be in contact with the second doped layer 3D2 through a metal thin film for ohmic contact.

On the fifth insulating layer 66, the ninth to sixteenth electrodes (layers) 112, 116, 120, 124, 128, 130, 134, and 138 are spaced apart from each other. According to one or more example embodiments, the ninth to sixteenth electrodes (layers) 112, 116, 120, 124, 128, 130, 134, and 138 are formed using a deposition method (e.g., CVD, PVD, sputtering, ALD, etc.) or a plating method, but the disclosure is not limited thereto.

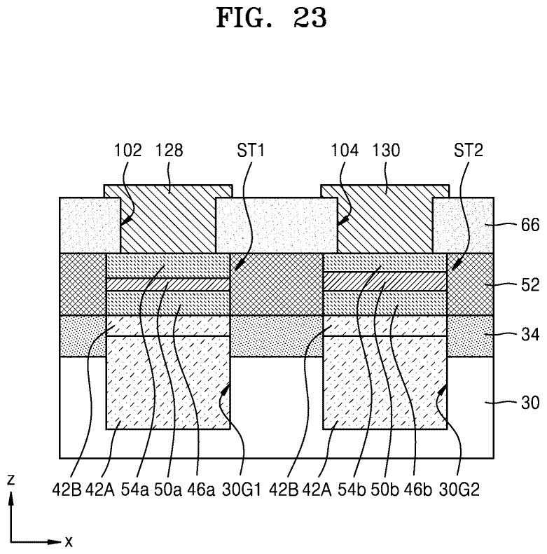

FIG. 23 shows a cross-sectional view taken along line 23-23′ of FIG. 22A.

Referring to FIG. 23, a side surface of the first layer structure ST1 and side surface of the second layer structure ST2 are in direct contact with side surfaces of the waveguide 52.

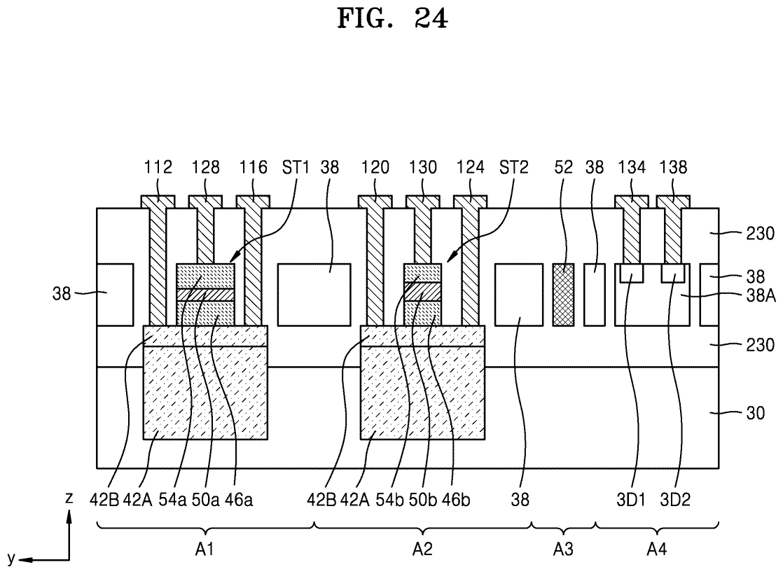

FIG. 24 shows an example case in which the first, second, fourth, and fifth insulating layers 34, 44, 62, and 66 in FIG. 22B all include the same material. In FIG. 24, a sixth insulating layer 230 collectively refers to the first, second, fourth, and fifth insulating layers 34, 44, 62, and 66 including the same material.

According to one or more example embodiments, as shown in FIG. 25, the first pattern 38A including the first and second doped layers 3D1 and 3D2 may be provided in a lateral direction of the waveguide 52, that is, in a direction perpendicular to the longitudinal direction of the waveguide 52. In this case as well, the first pattern 38A may be formed adjacent to the waveguide 52 so that the evanescent wave generated from the waveguide 52 may reach a channel between the first and second doped layers 3D1 and 3D2.

After forming the ninth to sixteenth electrodes 112, 116, 120, 124, 128, 130, 134, and 138, a process of forming a semiconductor device such as a complementary metal oxide semiconductor (CMOS) IC or a non-optical device may be performed. The semiconductor devices or non-optical devices may be components included in a photonic integrated circuit including a light source, a light modulator, a waveguide, and a light receiving element, and may be formed on a substrate on which the photonic integrated circuit is formed.

The semiconductor device or non-optical device may be formed at a relatively low temperature (e.g., a temperature lower than 500° C.) compared to an optical device such as a light source or light modulator formed by a growth method. Therefore, during the process of forming the semiconductor device or non-optical device, the already formed light source or light modulator may not be affected. In other words, while the semiconductor device or non-optical device is being formed, the characteristics of the previously formed light source or light modulator may not be deteriorated or degraded.

In the photonic integrated circuit according to an embodiment, the light source and light modulator are not bonded or formed on a substrate, but are selectively grown in grooves formed on the substrate and planarized to a height of the substrate. Accordingly, the occurrence of step differences may be prevented or minimized in the process of integrating a light source in a photonic integrated circuit, and problems caused by existing step differences may be resolved. Additionally, because the light source and the light modulator are formed in the groove of the substrate, heat generated during the operation of the light source or light modulator may be quickly discharged through a thin layer under the groove without passing through the insulating layer. In addition, because the light source and light modulator are based on GaN and are manufactured at a relatively high temperature compared to the CMOS logic process, after the light source and light modulator are formed, there is no concern that the characteristics of the light source and light modulator will deteriorate or degrade during the CMOS logic process. Therefore, at least in terms of process temperature, constraints on CMOS logic processing may be eliminated or minimized.

Also, the active layers of the light source and light modulator are located at the same height as the waveguide and are in direct contact with the waveguide. Therefore, light generated from the light source may be directly focused into the waveguide, and light reflection in the waveguide may be minimized.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A photonic integrated circuit comprising:
a substrate;
a light source on the substrate, the light source comprising a first active layer configured to emit light;
a light modulator on the substrate and optically connected to the light source, the light modulator comprising a second active layer configured to emit light; and
a waveguide on the substrate between the light source and the light modulator,
wherein the substrate comprises:
a first groove; and
a second groove spaced apart from the first groove,
wherein the light source is provided in the first groove,
wherein the light modulator is provided in the second groove,
wherein the first active layer and second active layer directly contact the waveguide, and
wherein each of a first height of the first active layer and a second height of the second active layer is between an upper surface of the waveguide and a lower surface of the waveguide.

2. The photonic integrated circuit of claim 1, wherein the light source comprises a GaN-based material and the light modulator comprises a GaN-based material.

3. The photonic integrated circuit of claim 1, wherein a first planar size of the first groove is same as a second planar size of the second groove, or a first depth of the first groove is the same as a second depth of the second groove.

4. The photonic integrated circuit of claim 1, wherein a first thickness of the first active layer is different from a second thickness of the second active layer.

5. The photonic integrated circuit of claim 1, wherein the substrate comprises:
a first semiconductor layer;
a first insulating layer on the first semiconductor layer; and
a second semiconductor layer on the first insulating layer,
wherein the first semiconductor layer forms a bottom portion of the first groove and a bottom portion of the second groove.

6. The photonic integrated circuit of claim 5, wherein the first semiconductor layer is a silicon layer, and the bottom portion of the first groove and the bottom portion of the second groove are (111) planes.

7. The photonic integrated circuit of claim 1, wherein a first width of the first active layer in a direction perpendicular to a length of the waveguide is greater than a second width of the second active layer.

8. The photonic integrated circuit of claim 5, wherein the substrate comprises a trench corresponding to a length of the waveguide,
wherein the trench penetrates the second semiconductor layer and has the first insulating layer as a bottom, and
wherein a third thickness of the waveguide is the same as a fourth thickness of the second semiconductor layer.

9. The photonic integrated circuit of claim 1, wherein the substrate comprises:
a first via hole comprising the first groove;
a second via hole comprising the second groove;
a third via hole comprising the waveguide; and
a fourth via hole comprising a first pattern, which is a part of the substrate.

10. The photonic integrated circuit of claim 9, wherein a first step is provided between the first via hole and the first groove, and
a second step is provided between the second via hole and the second groove.

11. The photonic integrated circuit of claim 9, wherein the first pattern comprises:
a first doped layer doped with a first dopant; and
a second doped layer spaced apart from the first doped layer and doped with a second dopant that is different from the first dopant.

12. The photonic integrated circuit of claim 11, wherein the first pattern is adjacent to the waveguide and configured to receive light leaking from the waveguide.

13. The photonic integrated circuit of claim 5, wherein the second semiconductor layer comprises:
a first via hole comprising the first groove;
a second via hole comprising the second groove;
a third via hole comprising the waveguide; and
a fourth via hole comprising a first pattern, which is a part of the substrate,
wherein the light source comprises:
a buffer layer and a first compound semiconductor layer provided in the first groove, the first compound semiconductor layer doped with an n-type dopant;
a second compound semiconductor layer provided on a first region of the first compound semiconductor layer;
the first active layer provided on the second compound semiconductor layer; and
a third compound semiconductor layer provided on the first active layer and doped with a p-type dopant,
wherein a first stack comprising the second compound semiconductor layer, the first active layer, and the third compound semiconductor layer is spaced apart from the second semiconductor layer, and
wherein a thickness of the first stack is equal to a thickness of the second semiconductor layer.

14. The photonic integrated circuit of claim 13, wherein the light modulator comprises:
the buffer layer and the first compound semiconductor layer in the second groove;
a fourth compound semiconductor layer on a second region of the first compound semiconductor layer in the second groove;
the second active layer on the fourth compound semiconductor layer; and
a fifth compound semiconductor layer on the second active layer and doped with a p-type dopant,
wherein a second stack comprising the fourth compound semiconductor layer, the second active layer, and the fifth compound semiconductor layer is spaced apart from the second semiconductor layer, and a thickness of the second stack is equal to a thickness of the second semiconductor layer, and
wherein a second area of the second region is less than a first area of the first region.

15. A method of manufacturing a photonic integrated circuit, the method comprising:
forming, on a substrate, a first groove, a second groove, a third groove and a fourth groove, the first groove defining a region for forming a light source, the second groove defining a region for forming a light modulator, the third groove defining a region for forming a waveguide, and the fourth groove defining a region for forming a light receiving element;
forming the waveguide in the third groove;
forming a first sub-groove with a first width less than a second width of the first groove, and forming a second sub-groove with a third width less than a fourth width of the second groove;
sequentially forming a first buffer layer and a first compound semiconductor layer doped with an n-type dopant in the first sub-groove;
sequentially forming a second buffer layer and the first compound semiconductor layer in the second sub-groove; and
forming a first stack including a first active layer on a first region on an upper surface of the first compound semiconductor layer in the first sub-groove and forming a second stack including a second active layer on a second region on the upper surface of the first compound semiconductor layer in the second sub-groove,
wherein the first stack and the second stack are formed simultaneously to have at a same height as the waveguide,
wherein the first sub-groove and the second sub-groove are formed simultaneously,
wherein the first buffer layer and the second buffer layer are formed simultaneously, and
wherein the first compound semiconductor layer in the first and second sub-grooves is formed simultaneously.

16. The method of claim 15, wherein a height of the upper surface of the first compound semiconductor layer in the first and second sub-grooves is the same as a height of a lower surface of the waveguide.

17. The method of claim 15, wherein a first area of the first region and a second area of the second region are different from each other.

18. The method of claim 15, wherein a first thickness of the first active layer is different from a second thickness of the second active layer.

19. An electronic apparatus comprising:
a photonic integrated circuit; and
a semiconductor device connected to the photonic integrated circuit,
wherein the photonic integrated circuit comprises:
a substrate;
a light source on the substrate, the light source comprising a first active layer configured to emit light;
a light modulator on the substrate and optically connected to the light source, the light modulator comprising a second active layer configured to emit light; and
a waveguide on the substrate between the light source and the light modulator,
wherein the substrate comprises:
a first groove; and
a second groove spaced apart from the first groove,
wherein the light source is provided in the first groove,
wherein the light modulator is provided in the second groove,
wherein the first active layer and second active layer directly contact the waveguide, and
wherein each of a first height of the first active layer and a second height of the second active layer is between an upper surface of the waveguide and a lower surface of the waveguide.

20. The electronic apparatus of claim 19, wherein the semiconductor device comprises at least one of a memory and a processor.
